(19) United States
(12) Patent Application Publication
(10) Pub. No.: US 2025/0299644 A1
(43) Pub. Date: Sep. 25, 2025

(54) DRIVING CIRCUIT AND DISPLAY DEVICE

(71) Applicant: BOE Technology Group Co., Ltd., Beijing (CN)

(72) Inventors: Peng Liu, Beijing (CN); Bailing Liu, Beijing (CN); Jing Feng, Beijing (CN); Liu Wu, Beijing (CN); Zhichong Wang, Beijing (CN); Chuanchuan Chang, Beijing (CN); Qian Zhang, Beijing (CN); Dong Liu, Beijing (CN)

(73) Assignee: BOE Technology Group Co., Ltd., Beijing (CN)

(21) Appl. No.: 18/861,281

(22) PCT Filed: Jan. 16, 2024
(86) PCT No.: PCT/CN2024/072530

§ 371 Date: Oct. 29, 2024

(30) Foreign Application Priority Data
Feb. 22, 2023 (CN) 202310187687.3

(51) Int. Cl. G09G 3/36; G11C 19/28; H03K 19/20

(52) U.S. Cl. CPC G09G 3/3677; G09G 2310/0286; G09G 2310/08; G09G 2330/021; G09G 2340/0435; G11C 19/28; H03K 19/20

(57) ABSTRACT

The present disclosure discloses a driving circuit and a display device. The driving circuit includes a plurality of driving units arranged in cascade, where each of the plurality of driving units is electrically connected to one or more rows of sub-pixels, the driving unit includes: a start row control module configured to specify one of the rows of sub-pixels as a switching start row under a control of a start row specified signal output by the start row specified signal line; a latch module configured to latch the start row specified signal; and a start row trigger module configured to trigger the switching start row to start scanning under a control of a trigger signal output by the trigger signal line.

### CROSS-REFERENCE TO RELATED APPLICATION

The present disclosure claims the priority of Chinese patent application filed on Feb. 22, 2023 before the CNIPA, China National Intellectual Property Administration with the application number of 202310187687.3, and the title of “DRIVING CIRCUIT AND DISPLAY DEVICE”, which is incorporated herein in its entirety by reference.

### FIELD

The present disclosure relates to the field of display technologies, and more particularly to a driving circuit and a display device.

### BACKGROUND

With the rapid development of display technologies, electronic products are updated very quickly, and tend to be light, thin and ultra-long standby. In order to improve customer experience, existing electronic products have longer requirements for standby time, and driving circuits of current display products are difficult to meet the requirements of low power consumption.

At present, it is urgent to provide a display device with strong driving ability, low power consumption and long standby time to meet development needs of the industry.

### SUMMARY

Embodiments of the present disclosure adopt the following technical solutions.

In a first aspect, there is provided a driving circuit, including: a plurality of driving units arranged in cascade, wherein each of the plurality of driving units is electrically connected to one or more rows of sub-pixels, and the driving unit includes:
a start row control module electrically connected to a first signal output terminal, a start row specified signal line and a first node of the driving unit at a current stage respectively, and configured to specify one of the rows of sub-pixels as a switching start row under a control of a start row specified signal output by the start row specified signal line;
a latch module electrically connected to the start row specified signal line, a reset signal line, a first level signal line, a second level signal line, the first node and a second node respectively, and configured to latch the start row specified signal; and
a start row trigger module electrically connected to the second node, a trigger signal line, the second level signal line and a third node respectively, and configured to trigger the switching start row to start scanning under a control of a trigger signal output by the trigger signal line.

In some embodiments of the present disclosure, the driving unit further includes:
a signal input module electrically connected to a first control signal line and a second control signal line respectively, and configured to input an enable signal to the switching start row under a common control of a signal output by the first control signal line and a signal output by the second control signal line and control the driving circuit to scan in a direction in which a number of rows of the sub-pixels decreases or in a direction in which the number of rows of the sub-pixels increases from the switching start row.

In some embodiments of the present disclosure, the driving unit further includes:
an end row control module electrically connected to the third node, the signal input module, an end row specified signal line, the second level signal line and a fifth node respectively, and configured to specify one of the rows of sub-pixels as a switching end row under a control of the enable signal output by the signal input module, a signal at a position of the third node and an end row specified signal input by the end row specified signal line.

In some embodiments of the present disclosure, the driving unit further includes:
a shift register module electrically connected to the fifth node, a first clock signal line, a second clock signal line, the reset signal line, the second level signal line, and the first signal output terminal and a second signal output terminal of the driving unit respectively, and configured to realize progressive scanning from the switching start row to the switching end row under a common control of a signal at a position of the fifth node. a first clock signal input by the first clock signal line and a second clock signal input by the second clock signal line.

In some embodiments of the present disclosure, the signal input module includes a forward scan input submodule and a reverse scan input submodule, wherein the forward scan input submodule and the reverse scan input submodule are connected together and electrically connected to the end row control module;
the forward scan input submodule is electrically connected to a forward scan signal line, the first control signal line and the second control signal line respectively, and is configured to output a forward scan signal transmitted by the forward scan signal line under a common control of a first control signal input by the first control signal line and a second control signal input by the second control signal line; and
the reverse scan input submodule is electrically connected to a reverse scan signal line, the first control signal line and the second control signal line respectively, and is configured to output a reverse scan signal transmitted by the reverse scan signal line under the common control of the first control signal input by the first control signal line and the second control signal input by the second control signal line,
wherein the end row control module is configured to receive the forward scan signal or the reverse scan signal, wherein the forward scan signal is configured to control the driving circuit to scan in the direction in which the number of rows of the sub-pixels increases from the switching start row, and the reverse scan signal is configured to control the driving circuit to scan in the direction in which the number of rows of the sub-pixels decreases from the switching start row.

In some embodiments of the present disclosure, the start row control module includes a first NAND gate sub-circuit and a first inverter.
wherein the first signal output terminal and the start row specified signal line of the driving unit at the current stage are electrically connected to two input terminals of the first NAND gate sub-circuit respectively, an input terminal of the first inverter is electrically connected to an output terminal of the first NAND gate sub-circuit, and an output terminal of the first inverter is electrically connected to the first node.

In some embodiments of the present disclosure, the latch module includes a first transistor, a first NOR gate sub-circuit, a second transistor, a third transistor and a fourth transistor, wherein
a gate of the first transistor is electrically connected to the reset signal line, a source of the first transistor is electrically connected to the start row specified signal line, and a drain of the first transistor is electrically connected to an input terminal of the first NOR gate sub-circuit and the second node respectively;
two input terminals of the first NOR gate sub-circuit are electrically connected to the first node and the second node respectively, and an output terminal of the first NOR gate sub-circuit is electrically connected to a gate of the third transistor and a gate of the fourth transistor respectively;
a gate of the second transistor is electrically connected to the reset signal line, a source of the second transistor is electrically connected to the first level signal line, and a drain of the second transistor is electrically connected to a source of the third transistor; and
a drain of the third transistor, a source of the fourth transistor and the second node are electrically connected together, and a drain of the fourth transistor is electrically connected to the second level signal line.

In some embodiments of the present disclosure, the start row trigger module includes a second inverter, a first transmission gate and a fifth transistor, wherein
an input terminal of the second inverter is electrically connected to the second node, and an output terminal of the second inverter is electrically connected to a gate of the fifth transistor and a first control terminal of the first transmission gate respectively;
a second control terminal of the first transmission gate is electrically connected to the second node, an input terminal of the first transmission gate is electrically connected to the trigger signal line, and an output terminal of the first transmission gate is electrically connected to the third node; and
a source of the fifth transistor is electrically connected to the second level signal line, and a drain of the fifth transistor is electrically connected to the third node.

In some embodiments of the present disclosure, the forward scan input submodule includes a second transmission gate, and the reverse scan input submodule includes a third transmission gate, wherein
a first control terminal of the second transmission gate is electrically connected to the first control signal line, a second control terminal of the second transmission gate is electrically connected to the second control signal line, an input terminal of the second transmission gate is electrically connected to the forward scan signal line, and an output terminal of the second transmission gate is connected to the end row control module;
a first control terminal of the third transmission gate is electrically connected to the second control signal line, a second control terminal of the third transmission gate is electrically connected to the first control signal line, an input terminal of the third transmission gate is electrically connected to the reverse scan signal line, and an output terminal of the third transmission gate is connected to the end row control module; and
the output terminal of the second transmission gate is connected to the output terminal of the third transmission gate.

In some embodiments of the present disclosure, the end row control module includes a third inverter, a fourth transmission gate, a sixth transistor, a second NOR gate sub-circuit and a fourth inverter, wherein
an input terminal of the third inverter is electrically connected to the end row specified signal line and a gate of the sixth transistor, and an output terminal of the third inverter is electrically connected to a second control terminal of the fourth transmission gate;
a first control terminal of the fourth transmission gate is electrically connected to the input terminal of the third inverter, an input terminal of the fourth transmission gate is electrically connected to the signal input module, and an output terminal of the fourth transmission gate is electrically connected to a fourth node;
a source of the sixth transistor is electrically connected to the second level signal line, and a drain of the sixth transistor is electrically connected to the fourth node; and
two input terminals of the second NOR gate sub-circuit are electrically connected to the third node and the fourth node respectively, an output terminal of the second NOR gate sub-circuit is electrically connected to an input terminal of the fourth inverter, and an output terminal of the fourth inverter is electrically connected to the fifth node.

In some embodiments of the present disclosure, the shift register module includes a fifth inverter, a first tri-state inverter, a second tri-state inverter, a fifth transmission gate, a sixth inverter, a seventh transistor and an eighth transistor, wherein
an input terminal of the fifth inverter is electrically connected to the first clock signal line, and an output terminal of the fifth inverter is electrically connected to a first control terminal of the first tri-state inverter and a second control terminal of the second tri-state inverter respectively;
a second control terminal of the first tri-state inverter is electrically connected to the first clock signal line, an input terminal of the first tri-state inverter is electrically connected to the fifth node, and an output terminal of the first tri-state inverter is electrically connected to a gate of the seventh transistor and an input terminal of the sixth inverter respectively;
a first control terminal of the second tri-state inverter is electrically connected to the first clock signal line, an input terminal of the second tri-state inverter is electrically connected to a sixth node, and an output terminal of the second tri-state inverter is electrically connected to the gate of the seventh transistor and the input terminal of the sixth inverter respectively;
an output terminal of the sixth inverter is electrically connected to the sixth node and the second signal output terminal of the driving unit at the current stage respectively;
a first control terminal of the fifth transmission gate is electrically connected to the output terminal of the first tri-state inverter and the output terminal of the second tri-state inverter respectively, a second control terminal of the fifth transmission gate is electrically connected to the output terminal of the sixth inverter, an input terminal of the fifth transmission gate is electrically connected to the second clock signal line, and an output terminal of the fifth transmission gate is electrically connected to the first signal output terminal of the driving unit at the current stage; and
a source of the seventh transistor is electrically connected to the second level signal line, a drain of the seventh transistor is electrically connected to the first signal output terminal of the driving unit at the current stage, a gate of the eighth transistor is electrically connected to the reset signal line, a source of the eighth transistor is electrically connected to the sixth node, and a drain of the eighth transistor is electrically connected to the second level signal line.

In some embodiments of the present disclosure, the latch module includes a first transistor, a second transistor, a third transistor and a fourth transistor, and the start row trigger module includes a fifth transistor,
wherein the first transistor, the fourth transistor, the fifth transistor, the sixth transistor, the seventh transistor and the eighth transistor have a same polarity, the second transistor and the third transistor have a same polarity, and a polarity of the first transistor is opposite to a polarity of the second transistor.

In some embodiments of the present disclosure, the first transistor, the fourth transistor, the fifth transistor, the sixth transistor, the seventh transistor and the eighth transistor are all N-type transistors, and the second transistor and the third transistor are all P-type transistors.

In some embodiments of the present disclosure, in a resolution trigger display frame stage, a signal output by the first signal output terminal of the driving unit connected to the switching start row is consistent with the start row specified signal.

In some embodiments of the present disclosure, in a resolution switching display frame stage, the signal output by the first signal output terminal of the driving unit connected to the switching start row is consistent with the start row specified signal.

In some embodiments of the present disclosure, in a resolution switching display frame stage, the start row specified signal is a low level signal with a constant voltage.

In some embodiments of the present disclosure, a falling edge of the trigger signal is aligned with a rising edge of the start row specified signal in the resolution switching display frame stage.

In some embodiments of the present disclosure, in the resolution switching display frame stage, the signal output by the first signal output terminal of the driving unit connected to the switching end row is consistent with the end row specified signal.

In some embodiments of the present disclosure, a pulse width of a clock signal in the resolution trigger display frame stage is less than a pulse width of a clock signal in the resolution switching display frame stage.

In some embodiments of the present disclosure, the driving unit connected to at least two adjacent rows of sub-pixels is electrically connected to a same clock signal line.

In a second aspect, the embodiments of the present disclosure provide display device, including the driving circuit according to any one of the first aspect.

In some embodiments of the present disclosure, when a resolution of a picture displayed in the resolution switching display frame stage is less than or equal to half of a resolution of a picture displayed in the resolution trigger display frame stage, a refresh rate in the resolution switching display frame stage is greater than a refresh rate in the resolution trigger display frame stage.

The above description is only an overview of the technical solutions of the present disclosure. In order to understand technical means of the present disclosure more clearly, it can be implemented according to contents of the specification, and in order to make the above and other purposes, features and advantages of the present disclosure more obvious and understandable, the specific embodiments of the present disclosure are provided below.

### BRIEF DESCRIPTION OF THE DRAWINGS

In order to more clearly explain the technical solutions in the embodiments of the present disclosure or the related art, drawings needed in the description of the embodiments or the related art will be briefly introduced below. Obviously, the drawings described below are only some embodiments of the present disclosure. For a person skilled in the art, other drawings can be obtained according to these drawings without creative work.

FIG. 1 is a schematic diagram of an area of a display screen of a display device provided by an embodiment of the present disclosure.

FIG. 2 is a schematic diagram of an area of a partial display screen of a display device provided by an embodiment of the present disclosure.

FIG. 3 is a schematic diagram of an area of a partial display screen of another display device provided by an embodiment of the present disclosure.

FIG. 4 is a circuit diagram of a driving circuit provided by an embodiment of the present disclosure.

FIG. 5 is a circuit diagram of another driving circuit provided by an embodiment of the present disclosure.

FIG. 6 is a circuit diagram of yet another driving circuit provided by an embodiment of the present disclosure.

FIG. 7 is a schematic diagram of a cascaded driving circuit provided by an embodiment of the present disclosure.

FIG. 8 is a timing diagram of conventional driving scanning of a driving circuit provided by an embodiment of the present disclosure.

FIG. 9 is a timing diagram of resolution switching of a driving circuit provided by an embodiment of the present disclosure.

FIG. 10 is a timing diagram of resolution switching of another driving circuit provided by an embodiment of the present disclosure.

FIG. 11 is a timing diagram of resolution switching of a driving unit connected to a previous row of a switching start row provided by an embodiment of the present disclosure.

FIG. 12 is a timing diagram of resolution switching of a driving unit connected to a switching start row provided by an embodiment of the present disclosure.

FIG. 13 is a timing diagram of resolution switching of a driving unit connected to a subsequent row of a switching start row provided by an embodiment of the present disclosure.

FIG. 14 is a timing diagram of resolution switching of a driving unit connected to a switching end row provided by an embodiment of the present disclosure.

FIG. 15 is a timing diagram of resolution switching of a driving unit connected to a subsequent row of a switching end row provided by an embodiment of the present disclosure.

FIG. 16 is an explanatory diagram of a relationship between signals in a timing diagram provided by an embodiment of the present disclosure.

FIG. 17 is a schematic timing diagram of signals for increasing a pulse width of a clock signal in a resolution switching frame stage provided by an embodiment of the present disclosure.

FIG. 18 is a schematic timing diagram of signals of a driving circuit for driving two rows of sub-pixels at the same time provided by an embodiment of the present disclosure.

### DETAILED DESCRIPTION

Technical solutions in embodiments of the present disclosure will be clearly and completely described below with reference to the drawings in the embodiments of the present disclosure. Obviously, the described embodiments are only a part of the embodiments of the present disclosure, but not the whole embodiments. Based on the embodiments of the present disclosure, all other embodiments obtained by a person skilled in the art without creative work belong to the protection scope of the present disclosure.

Unless the context requires otherwise, throughout the specification and claims, the term “including” is interpreted as an open and inclusive meaning, that is, “including but not limited to”. In the description of the specification, terms “one embodiment”. “some embodiments”, “exemplary embodiments”, “an example”, “specific examples” or “some examples” are intended to indicate that specific features, structures, materials or characteristics related to the embodiments or examples are included in at least one embodiment or example of the present disclosure. The schematic representations of the above terms do not necessarily refer to the same embodiment or example. In addition, the described specific features, structures, materials or characteristics may be included in any one or more embodiments or examples in any appropriate manner.

In the embodiments of the present disclosure, words “first”, “second”, “third” and “fourth” are used to distinguish the same or similar items with basically the same functions and effects, only to clearly describe the technical solutions of the embodiments of the present disclosure, and cannot be understood as indicating or implying relative importance or implicitly indicating the number of indicated technical features.

In this specification, “electrical connection” or “coupling” includes a case in which constitute essential factors are connected together through an element having some certain electrical effect. The “element having some electrical function” is not particularly limited as long as electrical signals between the connected constituent elements may be transmitted. Examples of the “element having some electrical function” not only include an electrode and a wiring, but also include a switch element such as a transistor, a resistor, an inductor, a capacitor, other elements with a plurality of functions, and the like.

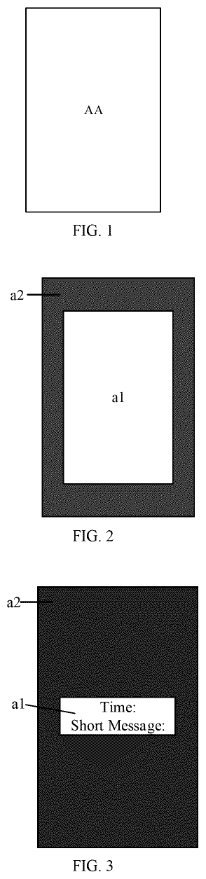

In the related art, referring to FIG. 1, in a case where a display device is displayed in full screen, a display area AA is all displayed, and a driving circuit will scan all sub-pixels line by line. When it is necessary to switch resolution or local display, referring to FIG. 2, in a case where a local area a1 of the display area AA is displayed, all sub-pixels can only be scanned line by line, so as to display at a desired resolution through a voltage control of signals.

For example, referring to FIG. 3, in a case where the display device only needs to display a time, a weather or a short message, a range of the local area al of the display area AA is relatively small, and it is still necessary to scan pixel rows in a dark area a2 as shown in FIG. 3, and thus the power consumption of local display is relatively large, and the standby time is seriously reduced.

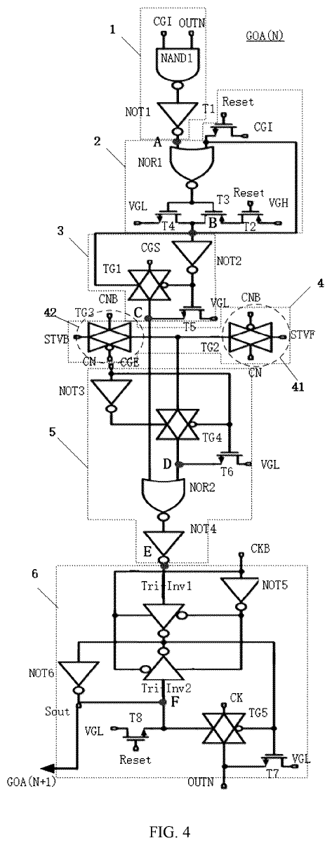

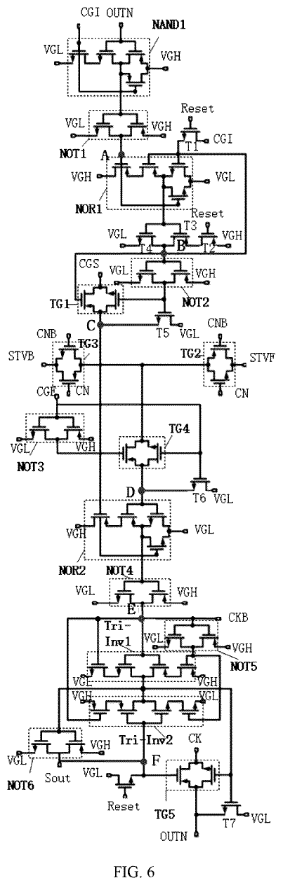

Based on this, embodiments of the present disclosure provide a driving circuit. As shown in FIG. 6, the driving circuit includes a plurality of driving units arranged in cascade, and each of the plurality of driving units is electrically connected to one or more rows of sub-pixels. As shown in FIG. 4, the driving unit includes:
a start row control module 1 electrically connected to a first signal output terminal OUTN, a start row specified signal line CGI (Control Gate Initial) and a first node A of the driving unit at a current stage respectively, and configured to specify one of the rows of sub-pixels as a switching start row under a control of a start row specified signal CGI output by the start row specified signal line CGI;
a latch module 2 electrically connected to the start row specified signal line CGI, a reset signal line Reset, a first level signal line (for example, a VGH line), a second level signal line (for example, a VGL line), the first node A and a second node B respectively, and configured to latch the start row specified signal CGI; and
a start row trigger module 3 electrically connected to the second node B, a trigger signal line CGS (Control Gate Start), the second level signal line (for example, the VGL line) and a third node C respectively, and configured to trigger the switching start row to start scanning under a control of a trigger signal CGS output by the trigger signal line CGS.

In the embodiments of the present disclosure, the driving circuit is an integrated gate driver on array (GOA) circuit. The GOA driving circuit technology is to directly fabricate gate driving circuits on an array substrate to realize a progressive scanning driving method, and is used in various display devices. GOA driving circuits can be directly fabricated on the array substrate, a process of binding drive integrated circuits (ICs) is omitted, thereby reducing the dependence of the array substrate on the relatively high cost drive ICs, reducing the cost, and also meeting the design requirements of narrow bezel and low power consumption of display products.

In some embodiments, the driving circuit includes a complementary metal oxide semiconductor (CMOS) gate circuit, and the CMOS gate circuit includes P-type MOS transistors and N-type MOS transistors.

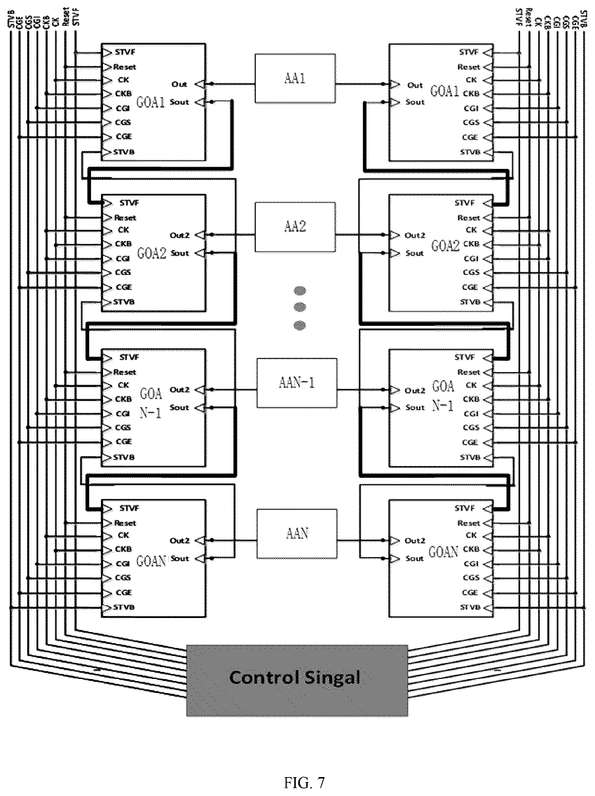

The driving circuit provided by the embodiments of the present disclosure includes a plurality of stages of cascaded driving units. Referring to FIG. 7, the plurality of stages of cascaded driving units include a first stage driving unit GOA1, a second stage driving unit GOA2 . . . , an (N−1)th stage driving unit GOAN-1 and an Nth stage driving unit GOAN, which are cascaded. The first stage driving unit is electrically connected to at least one row of sub-pixels in a display area AAI, the second stage driving unit is electrically connected to at least one row of sub-pixels in a display area AA2, . . . , the (N−1)th stage driving unit is electrically connected to at least one row of sub-pixels in a display area AAN-1 and the Nth stage driving unit is electrically connected to at least one row of sub-pixels in a display area AAN. In some embodiments, one of the driving units is electrically connected to one row of sub-pixels, that is, the driving unit can drive a pixel driving unit of one row of sub-pixels. In some embodiments, one of the driving units is electrically connected to two or more rows of sub-pixels, for example, the driving unit can drive pixel driving units of two rows of sub-pixels at the same time; and for another example, the driving unit can drive pixel driving units of three rows of sub-pixels at the same time. In this specification, taking that one row of sub-pixels is driven by one stage driving unit in the plurality of stages of driving units as an example for explanation, where the one stage driving unit includes two driving units.

It should be noted that in FIG. 4, taking a driving unit GOA(N) of the Nth stage driving unit as an example. In a forward scan mode, the Nth stage driving unit GOA(N) and an (N+1)th stage driving unit GOA(N+1) in FIG. 4 are electrically connected. It can be understood that in a reverse scan mode, the Nth stage driving unit GOA(N) and the (N−1)th stage driving unit GOA(N−1) are electrically connected.

In the embodiments of the present disclosure, a driving unit is arranged in a peripheral area located on at least one side of the display area AA. In some embodiments, a driving unit can be arranged in a peripheral area BB on one side of the display area AA, so that the cost of driving the sub-pixels is relatively low. In other embodiments, referring to FIG. 7, driving units can be respectively arranged in peripheral areas BB on left and right sides of the display area AA, so that two driving units at the same stage can drive a row of sub-pixels at the same time. For large-size display panels, the uniformity of signal transmission, the brightness uniformity of a display screen and the display performance can be improved. The details can be determined according to design requirements of display products.

Here, there is no limitation on display colors of respective sub-pixels in the above-mentioned display area AA. In some embodiments, the display colors of respective sub-pixels in the display area AA may be the same. For example, all sub-pixels display blue; and for another example, all sub-pixels display white. In other embodiments, the display area AA can include multiple sub-pixels with different display colors. For example, the display area AA can include three types of sub-pixels displaying red, blue and green at the same time: and for another example, the display area AA can include four types of sub-pixels displaying red, blue, green and white at the same time.

In exemplary embodiments, the first node A, the second node B and the third node C do not exist in fact, but are just concepts put forward for the convenience of describing circuit connection relationships in the driving units.

In exemplary embodiments, the start row control module 1 of the driving unit is configured to specify one of the rows of sub-pixels as a switching start row under a control of a start row specified signal CGI output by the start row specified signal line CGI. For example, when the start row specified signal CGI is a high level signal, the start row control module 1 is controlled to specify one of the rows of sub-pixels as the switching start row. The switching start row can be any row of sub-pixels from a first row of sub-pixels to an Nth row (the last row) of sub-pixels.

Taking that the start row control module 1 can be controlled to specify one of the rows of sub-pixels as the switching start row when the CGI signal is a high level signal as an example for explanation. In some embodiments, when a first output signal OUTN output by a first signal output terminal OUTN of the Nth stage driving unit and the CGI signal are both high level signals, the start row control module 1 can specify a row of sub-pixels electrically connected to the first signal output terminal OUTN of the Nth stage driving unit as the switching start row. For example, when a OUT3 signal output by a first signal output terminal OUT3 of a third stage driving unit and the CGI signal are both high level signals, the start row control module 1 can specify a row of sub-pixels electrically connected to the first signal output terminal OUT3 of the third stage driving unit as the switching start row. Since one row of sub-pixels is driven by one stage driving unit, a third row of sub-pixels is the switching start row at this time.

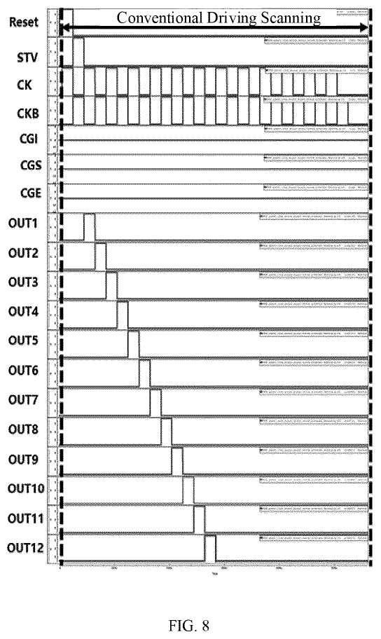

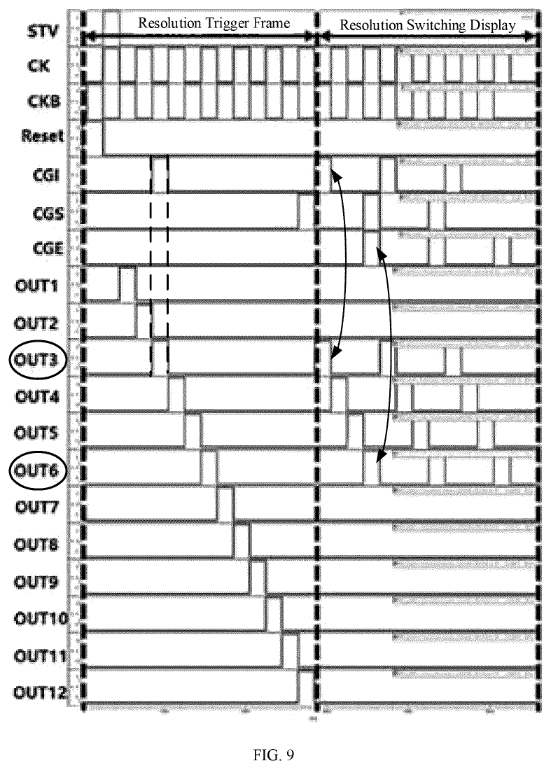

In a resolution trigger display frame stage, the CGI signal controls the start row control module 1 to specify a start row. It should be noted that, referring to FIG. 8 and FIG. 9. FIG. 8 shows a timing diagram of conventional progressive driving scanning of a driving circuit, and timings of first signal output terminals OUTN of respective stages of driving units in the resolution trigger display frame stage in FIG. 9 are the same as that in FIG. 8. In the resolution trigger display frame stage, respective rows of sub-pixels in the display area AA are still in a conventional progressive scanning mode.

The first signal output terminal OUTN of the Nth stage driving unit outputs the first output signal OUTN. For example, when the first output signal OUTN is a high level signal, the Nth row of sub-pixels can be charged. In the embodiments of the present disclosure, the first output signal OUTN of the driving unit is used as one of input signals of start row control modules 1 of the same stage driving unit.

The start row specified signal line CGI outputs the start row specified signal CGI, which is configured to control the start row control module 1 to specify one of the rows of sub-pixels as the switching start row.

The first node A is an output node of the start row control module 1, and the start row control module 1 inputs a signal to the latch module 2 through the first node A.

In exemplary embodiments, the latch module 2 is configured to latch the start row specified signal CGI. Specifically, the start row specified signal CGI is latched in a signal at a position of the second node B. For example, the start row specified signal CGI is latched in the signal at the position of the second node B in a form of a high level, and when there is no reset signal Reset input, the signal at the position of the second node B remains at the high level.

The reset signal Reset output by the reset signal line Reset can control the driving circuit to reset.

The first level signal line outputs a first level signal and the second level signal line outputs a second level signal. For example, a voltage of the first level signal is greater than a voltage of the second level signal. For example, the first level signal can be a high level signal VGH, and the second level signal can be a low level signal VGL.

The latch module 2 inputs a signal to the start row trigger module 3 through the second node B. The signal at the position of the second node B is related to the signal at the position of the first node A, the reset signal Reset, the first level signal (for example, the VGH signal) and the second level signal (for example, the VGL signal).

In exemplary embodiments, the start row trigger module 3 is configured to trigger the switching start row to start scanning under a control of a trigger signal CGS. Specifically, after the start row control module 1 specifies the switching start row, if the trigger signal CGS controls the start row trigger module 3 to trigger the switching start row to start scanning, a resolution of a next frame of a resolution trigger display frame is switched; and if the trigger signal CGS does not control the start row trigger module 3 to trigger the switching start row to start scanning, in some embodiments, the next frame of the resolution trigger display frame is still in a conventional progressive scanning state, and the resolution remains unchanged.

In some embodiments, when the trigger signal CGS is a high level signal, the start row trigger module 3 is controlled to trigger the switching start row to start scanning.

For example, referring to FIG. 9, in a resolution switching display frame stage, when the trigger signal CGS is a high level signal, it is triggered to start scanning from the third row of sub-pixels.

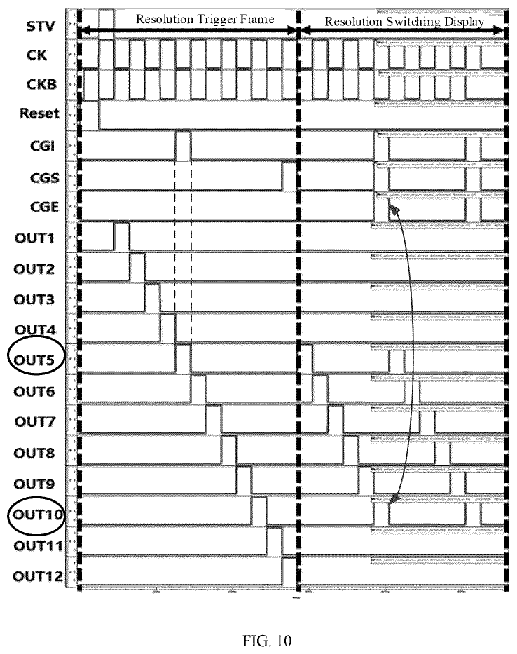

For example, referring to FIG. 10, in the resolution switching display frame stage, when the trigger signal CGS is a high level signal, it is triggered to start scanning from a fifth row of sub-pixels.

The third node C is an output node of the start row trigger module 3. The signal at the position of the third node C is related to the signal at the position of the second node B, the trigger signal CGS and the second level signal (for example, the VGL signal).

In the embodiments of the present disclosure, in the resolution trigger display frame stage, the start row control module 1 is configured to specify one of the rows of sub-pixels as the switching start row under the control of the start row specified signal CGI; and the latch module 2 is configured to latch the start row specified signal CGI. In the resolution switching display frame stage, the latch module 2 latches the switching start row as one row of sub-pixels specified by the start row control module 1; the start row trigger module 3 is configured to trigger the switching start row to start scanning under the control of the trigger signal CGS, and in the resolution switching display frame stage, the start row trigger module 3 is configured to trigger the switching start row latched by the latch module 2 to start scanning.

The embodiments of the present disclosure provide the driving circuit, including the plurality of driving units arranged in cascade, where each of the plurality of driving units is electrically connected to one or more rows of sub-pixels, and the driving unit includes: the start row control module 1 electrically connected to the first signal output terminal OUTN, the start row specified signal line CGI and the first node A of the driving unit at the current stage respectively, and configured to specify one of the rows of sub-pixels as the switching start row under the control of the start row specified signal CGI output by the start row specified signal line CGI; the latch module 2 electrically connected to the start row specified signal line CGI, the reset signal line Reset, the first level signal line (for example, the VGH line), the second level signal line (for example, the VGL line), the first node A and the second node B respectively, and configured to latch the start row specified signal CGI; and the start row trigger module 3 electrically connected to the second node B, the trigger signal line CGS, the second level signal line (for example, the VGL line) and the third node C respectively, and configured to trigger the switching start row to start scanning under a control of the trigger signal CGS output by the trigger signal line CGS. In this way, when full screen display is not needed or the electric quantity of the display device is relatively low, any row of sub-pixels can be specified as the switching start row, and scanning can be started from the specified switching start row, the data of some sub-pixels will not be updated, thereby reducing the power consumption of display and prolonging the standby time of the display device.

In some embodiments of the present disclosure, referring to FIG. 4, the driving unit further includes:
a signal input module 4 electrically connected to a first control signal line CNB and a second control signal line CN respectively, and configured to input an enable signal to the switching start row under a common control of a signal output by the first control signal line CNB and a signal output by the second control signal line CN and control the driving circuit to scan in a direction in which a number of rows of the sub-pixels decreases or in a direction in which the number of rows of the sub-pixels increases from the switching start row.

In the embodiments of the present disclosure, the enable signal includes a STV signal and a second output signal Sout of the driving unit at a previous stage or a next stage.

For example, in the case of scanning in the direction in which the number of rows of the sub-pixels increases, an enable signal of a first stage driving unit is the STV signal, and an enable signal of an Nth stage driving unit is the second output signal Sout of an (N−1)th stage driving unit. In the case of scanning in the direction in which the number of rows of the sub-pixels decreases, an enable signal of a last stage driving unit is the STV signal, and the enable signal of the Nth stage driving unit is the second output signal Sout of an (N+1)th stage driving unit.

The first control signal line CNB outputs a first control signal CNB, and the second control signal line CN outputs a second control signal CN.

In some embodiments, when the first control signal CNB is a high level signal and the second control signal CN is a low level signal, the signal input module 4 controls the driving circuit to scan in the direction in which the number of rows of the sub-pixels increases from the switching start row.

In some embodiments, when the first control signal CNB is a low level signal and the second control signal CN is a high level signal, the signal input module 4 controls the driving circuit to scan in the direction in which the number of rows of the sub-pixels decreases from the switching start row.

In the embodiments of the present disclosure, in the resolution trigger display frame stage, the start row control module 1 specifies one of the rows of sub-pixels as the switching start row. In the resolution switching display frame stage, the latch module 2 latches the switching start row as one row of sub-pixels specified by the start row control module 1. In the resolution switching display frame stage, the start row trigger module 3 is configured to trigger the switching start row latched by the latch module 2 to start scanning. After the start row trigger module 3 triggers the switching start row to start scanning, the signal input module 4 can control the driving circuit to scan in the direction in which the number of rows of the sub-pixels decreases or in the direction in which the number of rows of the sub-pixels increases from the switching start row.

In the embodiments of the present disclosure, by arranging the driving unit to further include the signal input module 4, which is electrically connected to the first control signal line CNB and the second control signal line CN respectively, and is configured to input the enable signal to the switching start row under the common control of the signal output by the first control signal line CNB and the signal output by the second control signal line CN and control the driving circuit to scan in the direction in which the number of rows of the sub-pixels decreases or in the direction in which the number of rows of the sub-pixels increases from the switching start row, it is realized that the driving circuit scans in the direction in which the number of rows of the sub-pixels decreases or in the direction in which the number of rows of the sub-pixels increases from the switching start row.

In some embodiments of the present disclosure, referring to FIG. 4, the driving unit further includes:
an end row control module 5 electrically connected to the third node C, the signal input module 4, an end row specified signal line CGE, the second level signal line (for example, the VGL line) and a fifth node E respectively, and configured to specify one of the rows of sub-pixels as a switching end row under a control of the enable signal STV output by the signal input module 4, a signal at a position of the third node C and an end row specified signal CGE input by the end row specified signal line CGE.

It should be noted that the fifth node E does not exist in fact, but is a concept put forward for the convenience of describing circuit connection relationships in the driving unit.

In exemplary embodiments, the end row control module 5 is configured to specify one of the rows of sub-pixels as the switching end row, where the switching end row is a sub-pixel row after a frame of scanning ends in the resolution switching display frame stage. After the end row control module 5 specifies the switching end row, the driving circuit will scan the sub-pixels line by line from the switching start row to the switching end row in the resolution switching display frame stage.

Multiple rows of sub-pixels that can be specified as the switching end row need to meet certain conditions. Specifically, when scanning along the direction in which the number of rows of the sub-pixels increases, the number of rows of the sub-pixels of the switching end row is greater than or equal to the number of rows of the sub-pixels of the switching start row. When scanning along the direction in which the number of rows of the sub-pixels decreases, the number of rows of the sub-pixels of the switching end row is less than or equal to the number of rows of the sub-pixels of the switching start row.

The end row specified signal CGE input by the end row specified signal line CGE includes a high level signal. For example, when the end row specified signal CGE is a high level signal, one of the multiple rows of sub-pixels can be specified as the switching end row.

For example, referring to FIG. 9, when the end row specified signal CGE is a high level signal, a sixth row of sub-pixels is specified as the switching end row. For example, referring to FIG. 10, when the end row specified signal CGE is a high level signal, a tenth row of sub-pixels is specified as the switching end row.

The fifth node E is an output node of the end row control module 5, and the signal at the position of the fifth node E is related to the signal at the position of the third node C, the end row specified signal CGB, the second level signal (for example, the VGL signal) and the signal input by the signal input module 4.

In the embodiments of the present disclosure, in the resolution trigger display frame stage, the start row control module 1 specifies one of the rows of sub-pixels as the switching start row. In the resolution switching display frame stage, the latch module 2 latches the switching start row as one row of sub-pixels specified by the start row control module 1. In the resolution switching display frame stage, the start row trigger module 3 is configured to trigger the switching start row latched by the latch module 2 to start scanning. After the start row trigger module 3 triggers the switching start row to start scanning, the signal input module 4 can control the driving circuit to scan in the direction in which the number of rows of the sub-pixels decreases or in the direction in which the number of rows of the sub-pixels increases from the switching start row. In the process that the signal input module 4 controls the driving circuit to scan in the direction in which the number of rows of the sub-pixels decreases or in the direction in which the number of rows of the sub-pixels increases, the end row control module 5 specifies one of the rows of sub-pixels as the switching end row, and in one frame of the resolution switching display frame stage, the driving circuit stops scanning after scanning the switching end row.

In the embodiments of the present disclosure, by arranging the driving unit to further include the end row control module 5, which is electrically connected to the third node C, the signal input module 4, the end row specified signal line CGE, the second level signal line (for example, the VGL line) and the fifth node E respectively, and is configured to specify one of the rows of sub-pixels as a switching end row under the control of the enable signal STV output by the signal input module 4, the signal at a position of the third node C and an end row specified signal CGE input by the end row specified signal line CGE, the start row control module 1 can specify any row of sub-pixels as the switching start row, and the end row control module 5 can specify one row of sub-pixels as the switching end row, in this way, the driving circuit starts scanning from the switching start row and stops scanning from the switching end row, and the data of some sub-pixels will not be updated, thereby reducing the display power consumption and prolonging the standby time of the display device.

In some embodiments of the present disclosure, referring to FIG. 4, the driving unit further includes:
a shift register module 6 electrically connected to the fifth node E, a first clock signal line, a second clock signal line, the reset signal line Reset, the second level signal line (for example. the VGL line), and the first signal output terminal OUTN and a second signal output terminal Sout of the driving unit respectively, and configured to realize progressive scanning from the switching start row to the switching end row under a common control of a signal at a position of the fifth node E, a first clock signal input by the first clock signal line and a second clock signal input by the second clock signal line.

The shift register module 6 is configured to realize progressive scanning from the switching start row to the switching end row. For example, whether the next row of sub-pixels is scanned can be controlled by the second output signal Sout output by the second signal output terminal Sout. Taking scanning in the direction in which the number of rows of the sub-pixels increases as an example, when the number of rows of the sub-pixels is greater than or equal to the number of rows of the switching start row and the number of rows of the sub-pixels is less than the number of rows of the switching end row, the driving unit electrically connected to the sub-pixels controls the driving unit at a next stage to scan the sub-pixels through the second output signal Sout.

In some embodiments, the first clock signal line is a CKB line, the first clock signal is a CKB signal, the second clock signal line is a CK line, and the second clock signal is a CK signal. In some embodiments, the first clock signal line is the CK line, the first clock signal is the CK signal, the second clock signal line is the CKB line, and the second clock signal is the CKB signal.

It should be noted that a pulse width of the first clock signal and a pulse width of the second clock signal are the same. When the first clock signal is a high level signal, the second clock signal is a low level signal; and when the first clock signal is a low level signal, the second clock signal is a high level signal.

In the embodiments of the present disclosure, the first output signal OUTN of the Nth stage driving unit is transmitted to a pixel driving circuit in an Nth stage display area AA.

Since a plurality of driving units are arranged in cascade, in the embodiments of the present disclosure,
in the case of scanning in the direction in which the number of rows of the sub-pixels increases, the second output signal Sout of the Nth stage driving unit can be used as an input signal of the (N+1)th stage driving unit, and it can be understood that the second signal output terminal Sout of the Nth stage driving unit can be electrically connected to the signal input module 4 of the (N+1)th stage driving unit; and

in the case of scanning in the direction in which the number of rows of the sub-pixels decreases, the second output signal Sout of the Nth stage driving unit can be used as an input signal of the (N−1)th stage driving unit, and it can be understood that the second signal output terminal Sout of the Nth stage driving unit can be electrically connected to the signal input module 4 of the (N−1)th stage driving unit.

In the embodiments of the present disclosure, in the resolution trigger display frame stage. the start row control module 1 specifies one of the rows of sub-pixels as the switching start row. In the resolution switching display frame stage, the latch module 2 latches the switching start row as one row of sub-pixels specified by the start row control module 1. In the resolution switching display frame stage, the start row trigger module 3 is configured to trigger the switching start row latched by the latch module 2 to start scanning. After the start row trigger module 3 triggers the switching start row to start scanning, the signal input module 4 can control the driving circuit to scan in the direction in which the number of rows of the sub-pixels decreases or in the direction in which the number of rows of the sub-pixels increases from the switching start row. In the resolution switching display frame stage, the end row control module 5 specifies one of the rows of sub-pixels as the switching end row. In the resolution switching display frame stage, the shift register module 6 realizes progressive scanning from the switching start row specified by the start row control module 1 to the switching end row specified by the end row control module 5.

In the embodiments of the present disclosure, by arranging the driving unit to further include the shift register module 6, which is electrically connected to the fifth node E, the first clock signal line, the second clock signal line, the reset signal line Reset, the second level signal line (for example, the VGL line), and the first signal output terminal OUTN and the second signal output terminal Sout of the driving unit respectively, and is configured to realize progressive scanning from the switching start row to the switching end row under the common control of the signal at the position of the fifth node E, the first clock signal input by the first clock signal line and the second clock signal input by the second clock signal line, in this way, the driving circuit can realize progressive scanning from the switching start row to the switching end row, and realize the partial display in the display area AA.

In some embodiments of the present disclosure, referring to FIG. 4, the signal input module 4 includes a forward scan input submodule 41 and a reverse scan input submodule 42. The forward scan input submodule 41 and the reverse scan input submodule 42 are connected together and electrically connected to the end row control module 5.

The forward scan input submodule 41 is electrically connected to a forward scan signal line STVF, the first control signal line CNB and the second control signal line CN respectively, and is configured to output a forward scan signal STVF transmitted by the forward scan signal line STVF under a common control of a first control signal CNB input by the first control signal line CNB and a second control signal CN input by the second control signal line CN.

The reverse scan input submodule 42 is electrically connected to a reverse scan signal line STVB, the first control signal line CNB and the second control signal line CN respectively, and is configured to output a reverse scan signal STVB transmitted by the reverse scan signal line STVB under the common control of the first control signal CNB input by the first control signal line CNB and the second control signal CN input by the second control signal line CN.

The end row control module 5 is configured to receive the forward scan signal STVF or the reverse scan signal STVB, wherein the forward scan signal STVF is configured to control the driving circuit to scan in the direction in which the number of rows of the sub-pixels increases from the switching start row, and the reverse scan signal STVB is configured to control the driving circuit to scan in the direction in which the number of rows of the sub-pixels decreases from the switching start row.

In the embodiments of the present disclosure, the forward scan input submodule 41 and the reverse scan input submodule 42 are connected together, where the connection is different from the electrical connection. The forward scan input submodule 41 and the reverse scan input submodule 42 do not form a path, that is, the signal output by the forward scan input submodule 41 will not be transmitted to the reverse scan input submodule 42, and the signal output by the reverse scan input submodule 42 will not be transmitted to the forward scan input submodule 41.

In some embodiments, when the first control signal CNB is a high level signal and the second control signal CN is a low level signal, the forward scan input submodule 41 and the end row control module 5 form a path, and the forward scan input submodule 41 inputs the forward scan signal STVF to the end row control module 5. In some embodiments, when the first control signal CNB is a low level signal and the second control signal CN is a high level signal, the reverse scan input submodule 42 and the end row control module 5 form a path, and the reverse scan input submodule 42 inputs the reverse scan signal STVB to the end row control module 5.

The forward scan signal STVF controls the driving circuit to scan in the direction in which the number of rows of the sub-pixels increases from the switching start row, which is called a forward scan mode. The reverse scan signal STVB controls the driving circuit to scan in the direction in which the number of rows of the sub-pixels decreases from the switching start row, which is called a reverse scan mode.

In the embodiments of the present disclosure, in the forward scan mode, the second signal output terminal Sout of the Nth stage driving unit is electrically connected to the forward scan signal line STVF of the (N+1)th stage driving unit; and in the reverse scan mode, the second signal output terminal Sout of the Nth stage driving unit is electrically connected to the reverse scan signal line STVB of the (N−1)th stage driving unit. In exemplary embodiments, the forward scan input submodule 41 can control a display panel to scan in the direction in which the number of rows of the sub-pixels increases, for example, scanning line by line from top to bottom. When the display panel has a rotation function and is displayed after rotating by about 180°, the reverse scan input submodule 42 can control the display panel to scan in the direction in which the number of rows of the sub-pixels decreases, for example, scanning line by line from top to bottom, which broadens application scenarios of the display panel, for example, the display panel can be applied to commercial display products or billboards with rotation function.

In the embodiments of the present disclosure, in the resolution trigger display frame stage, the start row control module 1 specifies one of the rows of sub-pixels as the switching start row.

In the resolution switching display frame stage, the latch module 2 latches the switching start row as one row of sub-pixels specified by the start row control module 1. In the resolution switching display frame stage, the start row trigger module 3 is configured to trigger the switching start row latched by the latch module 2 to start scanning.

After the start row trigger module 3 triggers the switching start row to start scanning, the forward scan input submodule 41 inputs the forward scan signal STVF to the end row control module 5 to control the driving circuit to scan in the direction in which the number of rows of the sub-pixels increases from the switching start row, or the reverse scan input submodule 42 inputs the reverse scan signal STVB to the end row control module 5 to control the driving circuit to scan in the direction in which the number of rows of the sub-pixels increases from the switching start row.

In the resolution switching display frame stage, the end row control module 5 specifies one of the rows of sub-pixels as the switching end row. In the resolution switching display frame stage, the shift register module 6 realizes progressive scanning from the switching start row specified by the start row control module 1 to the switching end row specified by the end row control module 5.

In the embodiments of the present disclosure, by arranging the signal input module 4 to include the forward scan input submodule 41 and the reverse scan input submodule 42; where the forward scan input submodule 41 and the reverse scan input submodule 42 are connected together and electrically connected to the end row control module 5; the forward scan input submodule 41 is configured to output a forward scan signal STVF transmitted by the forward scan signal line STVF; the reverse scan input submodule 42 is configured to output a reverse scan signal STVB transmitted by the reverse scan signal line STVB; the forward scan signal STVF is configured to control the driving circuit to scan in the direction in which the number of rows of the sub-pixels increases from the switching start row, and the reverse scan signal STVB is configured to control the driving circuit to scan in the direction in which the number of rows of the sub-pixels decreases from the switching start row; in this way, the driving circuit can realize forward scan or reverse scan from the switching start row to the switching end row.

In some embodiments of the present disclosure, referring to FIG. 4, the start row control module 1 includes a first NAND gate sub-circuit NAND1 and a first inverter NOT1.

The first signal output terminal OUTN and the start row specified signal line CGI of the driving unit at the current stage are electrically connected to two input terminals of the first NAND gate sub-circuit NAND1 respectively, an input terminal of the first inverter NOT1 is electrically connected to an output terminal of the first NAND gate sub-circuit NAND1, and an output terminal of the first inverter NOT1 is electrically connected to the first node A.

The NAND gate sub-circuit NAND includes two input terminals and an output terminal. When signals input by the two input terminals are high level signals, the output terminal outputs a low level signal; and when the signal input by at least one input terminal is a low level signal, the output terminal outputs a high level signal.

Taking the high level signal as 1 and the low level signal as 0 as an example, a truth table of the NAND gate sub-circuit NAND is shown in Table 1.

TABLE 1
Truth Table of NAND gate sub-circuit NAND

| First Input Signal | Second Input Signal | Output Signal |
|---|---|---|
| 1 | 1 | 0 |
| 1 | 0 | 1 |
| 0 | 1 | 1 |
| 0 | 0 | 1 |

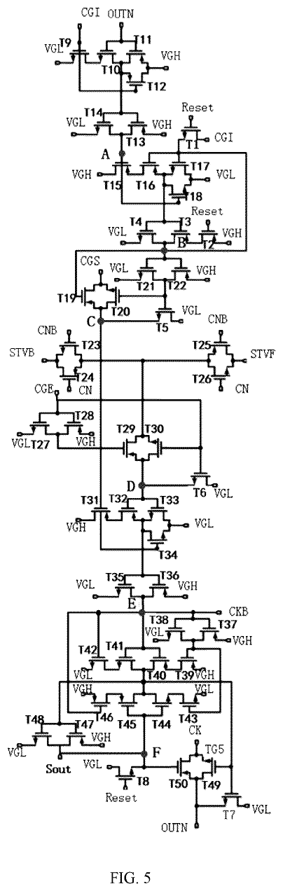

In the embodiments of the present disclosure, referring to FIG. 5 and FIG. 6, the first NAND gate sub-circuit NAND1 includes a ninth transistor T9, a tenth transistor T10, an eleventh transistor T11 and a twelfth transistor T12.

It should be noted that FIG. 5 and FIG. 6 have different labels for the same figure. Since there are many labels in the figure, in order to avoid confusion caused by overlapping labels. transistors are labeled in FIG. 5 and devices are labeled in FIG. 6.

The transistors include N-type transistors and P-type transistors. When the gate signal is a high level signal, the N-type transistors are turned on; and when the gate signal is a low level signal, the N-type transistor is turned off. When the gate signal is the high level signal, the P-type transistor are turned off; and when the gate signal is a low level signal, the P-type transistor is turned on.

In the embodiments of the present disclosure, the transistors include metal oxide semiconductor (MOS) transistors, for example, metal oxide semiconductor field effect transistors. The ninth transistor T9 is an N-type MOS transistor, the tenth transistor T10 is an N-type MOS transistor, the eleventh transistor T11 is a P-type MOS transistor and the twelfth transistor T12 is a P-type MOS transistor.

A gate of the ninth transistor T9 is electrically connected to the start row specified signal line CGI, a drain of the ninth transistor T9 is electrically connected to the second level signal line VGL, and a source of the ninth transistor T9 is electrically connected to a drain of the tenth transistor T10.

A gate of the tenth transistor T10 is electrically connected to the first signal output terminal OUTN of the driving unit at the current stage, and a source of the tenth transistor T10, a drain of the eleventh transistor T11, a source of the twelfth transistor T12 and the input terminal of the first inverter NOT1 are electrically connected together.

A gate of the eleventh transistor T11 is electrically connected to the first signal output terminal OUTN of the driving unit at the current stage, and a source of the eleventh transistor T11, a drain of the twelfth transistor T12 and the first level signal line VGH are electrically connected together.

A gate of the twelfth transistor T12 is electrically connected to the start row specified signal line CGI.

The inverter NOT includes an input terminal and an output terminal. When a signal input by the input terminal is a high level signal, a low level signal is output; and when the signal input by the input terminal is a low level signal, a high level signal is output.

The inverter NOT appearing in this specification is described here with reference, which will not be repeated.

In the embodiments of the present disclosure, referring to FIG. 5 and FIG. 6, the first inverter NOT1 includes a thirteenth transistor T13 and a fourteenth transistor T14.

The thirteenth transistor T13 is a P-type transistor and the fourteenth transistor T14 is an N-type transistor.

A gate of the thirteenth transistor T13, a gate of the fourteenth transistor T14 and the output terminal of the first NAND gate sub-circuit NAND1 are electrically connected together.

A source of the thirteenth transistor T13 is electrically connected to the first level signal line VGH, and a drain of the fourteenth transistor T14 is electrically connected to the second level signal line VGL.

A drain of the thirteenth transistor T13, a source of the fourteenth transistor T14 and the first node A are electrically connected together.

In the embodiments of the present disclosure, the start row control module 1 includes P-type MOS transistors and N-type MOS transistors, a positive voltage and a negative voltage output by the start row control module 1 have no loss, and the charging rate is fast and the efficiency is the same when outputting the positive voltage and the negative voltage, and thus the driving force of the driving circuit can be enhanced, and the display stability of the display device can be further improved.

In some embodiments of the present disclosure, referring to FIG. 4, the latch module 2 includes a first transistor T1, a first NOR gate sub-circuit NOR1, a second transistor T2, a third transistor T3 and a fourth transistor T4.

A gate of the first transistor T1 is electrically connected to the reset signal line Reset, a source of the first transistor T1 is electrically connected to the start row specified signal line CGI, and a drain of the first transistor T1 is electrically connected to an input terminal of the first NOR gate sub-circuit NOR1 and the second node B respectively.

Two input terminals of the first NOR gate sub-circuit NOR1 are electrically connected to the first node A and the second node B respectively, and an output terminal of the first NOR gate sub-circuit NOR1 is electrically connected to a gate of the third transistor T3 and a gate of the fourth transistor T4 respectively.

A gate of the second transistor T2 is electrically connected to the reset signal line Reset, a source of the second transistor T2 is electrically connected to the first level signal line VGH, and a drain of the second transistor T2 is electrically connected to a source of the third transistor T3.

A drain of the third transistor T3, a source of the fourth transistor T4 and the second node B are electrically connected together, and a drain of the fourth transistor T4 is electrically connected to the second level signal line VGL.

For the NOR gate sub-circuit NOR, when signals input by two input terminals are low level signals, a high level signal is output; and when at least one of the signals input by the two input terminals is a high level signal, a low level signal is output.

Taking the high level signal as 1 and the low level signal as 0 as an example, a truth table of the NOR gate sub-circuit NOR is shown in Table 2.

TABLE 2
Truth Table of NOR gate sub-circuit NOR

| First Input Signal | Second Input Signal | Output Signal |
|---|---|---|
| 1 | 1 | 0 |
| 1 | 0 | 0 |
| 0 | 1 | 0 |
| 0 | 0 | 1 |

The NOR gate sub-circuit NOR appearing in this specification is described here with reference, which will not be repeated.

In the embodiments of the present disclosure, referring to FIG. 5 and FIG. 6, the first NOR gate sub-circuit NOR1 includes a fifteenth transistor T15, a sixteenth transistor T16, a seventeenth transistor T17 and an eighteenth transistor T18.

The fifteenth transistor T15 is a P-type MOS transistor, the sixteenth transistor T16 is a P-type MOS transistor, the seventeenth transistor T17 is an N-type MOS transistor and the eighteenth transistor T18 is an N-type MOS transistor.

A gate of the fifteenth transistor TIS is electrically connected to the first node A, a drain of the fifteenth transistor T15 is electrically connected to the first level signal line VGH, and a source of the fifteenth transistor T15 is electrically connected to a drain of the sixteenth transistor T16.

A gate of the sixteenth transistor T16 is electrically connected to the drain of the first transistor T1, and a source of the sixteenth transistor T16, a drain of the seventeenth transistor T17, a source of the eighteenth transistor T18 and an input terminal of the second inverter NOT2 are electrically connected together.

A gate of the seventeenth transistor T17 is electrically connected to the drain of the first transistor T1, and a source of the seventeenth transistor T17, a drain of the eighteenth transistor T18 and the second level signal line VGL are electrically connected together.

A gate of the eighteenth transistor T18 is electrically connected to the first node A.

In the embodiments of the present disclosure, for example, referring to FIG. 4, the first transistor T1 is an N-type MOS transistor, the second transistor T1 is a P-type MOS transistor, the third transistor T3 is a P-type MOS transistor and the fourth transistor T4 is an N-type MOS transistor

In the embodiments of the present disclosure, the latch module 2 includes the first transistor T1, the first NOR gate sub-circuit NOR1, the second transistor T2, the third transistor T3 and the fourth transistor T4, the latch module 2 includes P-type MOS transistors and N-type MOS transistors, a positive voltage and a negative voltage output by the latch module 2 have no loss, and the charging rate is fast and the efficiency is the same when outputting the positive voltage and the negative voltage, and thus the driving force of the driving circuit can be enhanced, and the display stability of the display device can be further improved.

In some embodiments of the present disclosure, the start row trigger module 3 includes a second inverter NOT2, a first transmission gate TG1 and a fifth transistor T5.

An input terminal of the second inverter NOT2 is electrically connected to the second node B, and an output terminal of the second inverter NOT2 is electrically connected to a gate of the fifth transistor T5 and a first control terminal of the first transmission gate TG1 respectively.

A second control terminal of the first transmission gate TG1 is electrically connected to the second node B, an input terminal of the first transmission gate TG1 is electrically connected to the trigger signal line CGS, and an output terminal of the first transmission gate TG1 is electrically connected to the third node C.

A source of the fifth transistor T5 is electrically connected to the second level signal line VGL, and a drain of the fifth transistor is electrically connected to the third node C.

It should be noted that in this specification, an end marked with a circle on a transmission gate symbol in FIG. 4 is the first control terminal of the transmission gate.

The transmission gate TG includes a first control terminal, a second control terminal, an input terminal and an output terminal.

When the first control terminal is a low level signal and the second control terminal is a high level signal, the transmission gate TG is turned on, if the input terminal inputs a high level signal, the output terminal outputs a high level signal; and if the input terminal inputs a low level signal, the output terminal outputs a high level signal.

When the first control terminal is a high level signal and the second control terminal is a low level signal, the transmission gate TG is turned off, and the output terminal of the transmission gate TG does not output a signal.

The transmission gate TG appearing in this specification is described here with reference. which will not be repeated.

In the embodiments of the present disclosure, referring to FIG. 5 and FIG. 6, the first transmission gate TG1 includes a nineteenth transistor T19 and a twentieth transistor T20.

The nineteenth transistor T19 is a P-type MOS transistor and the twentieth transistor T20 is an N-type MOS transistor.

A gate of the nineteenth transistor T19 is electrically connected to the second node B, a source of the nineteenth transistor, the third node C and a source of the twentieth transistor T20 are electrically connected, and a drain of the nineteenth transistor, the trigger signal line CGS and a drain of the twentieth transistor T20 are electrically connected.

A gate of the twentieth transistor T20 is electrically connected to the output terminal of the second inverter NOT2.

In the embodiments of the present disclosure, referring to FIG. 5 and FIG. 6, the second inverter NOT2 includes a twenty-first transistor T21 and a twenty-second transistor T22.

The twenty-first transistor T21 is an N-type MOS transistor and the twenty-second transistor T22 is a P-type MOS transistor.

A gate of the twenty-first transistor T21, a gate of the twenty-second transistor T22 and the second node B are electrically connected together.

A drain of the twenty-first transistor T21 is electrically connected to the second level

signal line VGL, and a source of the twenty-second transistor T22 is electrically connected to the first level signal line VGH.

A source of the twenty-first transistor T21, a drain of the twenty-second transistor T22 and the gate of the fifth transistor T5 are electrically connected together.

In the embodiments of the present disclosure, for example, referring to FIG. 4, the fifth transistor T5 is an N-type MOS transistor.

In the embodiments of the present disclosure, the start row trigger module 3 includes the second inverter NOT2, the first transmission gate TG1 and the fifth transistor t5; the start row trigger module 3 includes P-type MOS transistors and N-type MOS transistors, a positive voltage and a negative voltage output by the start row trigger module 3 have no loss, and the charging rate is fast and the efficiency is the same when outputting the positive voltage and the negative voltage, and thus the driving force of the driving circuit can be enhanced, and the display stability of the display device can be further improved.

In some embodiments of the present disclosure, the forward scan input submodule 41 includes a second transmission gate TG2, and the reverse scan input submodule 42 includes a third transmission gate TG3.

A first control terminal of the second transmission gate TG2 is electrically connected to the first control signal line CNB, a second control terminal of the second transmission gate TG2 is electrically connected to the second control signal line CN, an input terminal of the second transmission gate TG2 is electrically connected to the forward scan signal line STVF, and an output terminal of the second transmission gate TG2 is connected to the end row control module 5.

A first control terminal of the third transmission gate TG3 is electrically connected to the second control signal line CN, a second control terminal of the third transmission gate TG3 is electrically connected to the first control signal line CNB, an input terminal of the third transmission gate TG3 is electrically connected to the reverse scan signal line STVF, and an output terminal of the third transmission gate TG3 is connected to the end row control module 5.

The output terminal of the second transmission gate TG2 is connected to the output terminal of the third transmission gate TG3.

In the embodiments of the present disclosure, the output terminal of the second transmission gate TG2 is connected to the output terminal of the third transmission gate TG3, where the connection and electrical connection are different, and the output terminal of the second transmission gate TG2 and the output terminal of the third transmission gate TG3 do not form a path.

In the embodiments of the present disclosure, referring to FIG. S and FIG. 6, the third transmission gate TG3 includes a twenty-third transistor T23 and a twenty-fourth transistor T24.

The twenty-third transistor T23 is an N-type MOS transistor and the twenty-fourth transistor T24 is a P-type MOS transistor.

A gate of the twenty-third transistor T23 is electrically connected to the first control signal line CNB, a source of the twenty-third transistor T23 is electrically connected to a source of the twenty-fourth transistor T24, and a drain of the twenty-third transistor T23, the reverse scan signal line STVB and a drain of the twenty-fourth transistor T24 are electrically connected.

A gate of the twenty-fourth transistor T24 is electrically connected to the second control signal line CN.

In the embodiments of the present disclosure, referring to FIG. 5 and FIG. 6, the second transmission gate TG2 includes a twenty-fifth transistor T25 and a twenty-sixth transistor T26.

The twenty-fifth transistor T25 is a P-type MOS transistor, and the twenty-sixth transistor T26 is an N-type MOS transistor.

A gate of the twenty-fifth transistor T25 is electrically connected to the first control signal line CNB, a source of the twenty-fifth transistor T25 is electrically connected to a source of the twenty-sixth transistor T26, and a drain of the twenty-fifth transistor T25, the forward scan signal line STVF and a drain of the twenty-sixth transistor T26 are electrically connected.

A gate of the twenty-sixth transistor T26 is electrically connected to the second control signal line CN. In some embodiments of the present disclosure, the forward scan input submodule 41 includes the second transmission gate TG2, and the reverse scan input submodule 42 includes the third transmission gate TG3, the forward scan input submodule 41 and the reverse scan input submodule 42 include P-type MOS transistors and N-type MOS transistors, a positive voltage and a negative voltage output by the forward scan input submodule 41 or the reverse scan input submodule 42 have no loss, and the charging rate is fast and the efficiency is the same when outputting the positive voltage and the negative voltage, and thus the driving force of the driving circuit can be enhanced, and the display stability of the display device can be further improved.

In some embodiments of the present disclosure, referring to FIG. 4, the end row control module 5 includes a third inverter NOT3, a fourth transmission gate TG4, a sixth transistor T6, a second NOR gate sub-circuit NOR2 and a fourth inverter NOT4.

An input terminal of the third inverter NOT3 is electrically connected to the end row specified signal line CGE and a gate of the sixth transistor T6, and an output terminal of the third inverter NOT3 is electrically connected to a second control terminal of the fourth transmission gate TG4.

A first control terminal of the fourth transmission gate TG4 is electrically connected to the input terminal of the third inverter NOT3, an input terminal of the fourth transmission gate TG4 is electrically connected to the signal input module 4, and an output terminal of the fourth transmission gate TG4 is electrically connected to a fourth node D.

A source of the sixth transistor T6 is electrically connected to the second level signal line VGL, and a drain of the sixth transistor T6 is electrically connected to the fourth node D.

Two input terminals of the second NOR gate sub-circuit NOR2 are electrically connected to the third node C and the fourth node D respectively, an output terminal of the second NOR gate sub-circuit NOR2 is electrically connected to an input terminal of the fourth inverter NOT4, and an output terminal of the fourth inverter NOT4 is electrically connected to the fifth node E.

In the embodiments of the present disclosure, referring to FIG. 5 and FIG. 6, the third inverter NOT3 includes a twenty-seventh transistor T27 and a twenty-eighth transistor T28.

The twenty-seventh transistor T27 is an N-type MOS transistor and the twenty-eighth transistor T28 is a P-type MOS transistor.

A gate of the twenty-seventh transistor T27, a gate of the twenty-eighth transistor T28 and the end row specified signal line CGE are electrically connected together.

A drain of the twenty-seventh transistor T27 is electrically connected to the second level signal line VGL, and a source of the twenty-eighth transistor T28 is electrically connected to the first level signal line VGH.

A source of the twenty-seventh transistor T27, a drain of the twenty-eighth transistor T28 and the second control terminal of the fourth transmission gate TG4 are electrically connected together.

In the embodiments of the present disclosure, referring to FIG. 5 and FIG. 6, the fourth transmission gate TG4 includes a twenty-ninth transistor T29 and a 30th transistor T30.

The twenty-ninth transistor T29 is a P-type MOS transistor and the thirtieth transistor T30 is an N-type MOS transistor.

A gate of the twenty-ninth transistor T29 is electrically connected to the output terminal of the third inverter NOT3, a source of the twenty-ninth transistor T29, a source of the thirtieth transistor T30 and the fourth node D are electrically connected, and a drain of the twenty-ninth transistor T29, the signal input module 4 and a drain of the thirtieth transistor T30 are electrically connected.

A gate of the thirtieth transistor T30 is electrically connected to the end row specified signal line CGE. In the embodiments of the present disclosure, referring to FIG. 5 and FIG. 6, the second NOR gate sub-circuit NOR2 includes a thirty-first transistor T31, a thirty-second transistor T32, a thirty-third transistor T33 and a thirty-fourth transistor T34.

The thirty-first transistor T31 is a P-type MOS transistor, the thirty-second transistor T32 is a P-type MOS transistor, the thirty-third transistor T33 is an N-type MOS transistor and the thirty-fourth transistor T34 is an N-type MOS transistor.

A gate of the thirty-first transistor T31 is electrically connected to the third node C, a drain of the thirty-first transistor T31 is electrically connected to the first level signal line VGH, and a source of the thirty-first transistor T31 is electrically connected to a drain of the thirty-second transistor T32.

A gate of the thirty-second transistor T32 is electrically connected to the fourth node D. and a source of the thirty-second transistor T32, a drain of the thirty-third transistor T33, a source of the thirty-fourth transistor T34 and the input terminal of the fourth inverter NOT4 are electrically connected together.

A gate of the thirty-third transistor T33 is electrically connected to the fourth node D, and a source of the thirty-third transistor T33, a drain of the thirty-fourth transistor T34 and the second level signal line VGL are electrically connected together.

A gate of the thirty-fourth transistor T34 is electrically connected to the third node C.

In the embodiments of the present disclosure, referring to FIG. 5 and FIG. 6, the fourth inverter NOT4 includes a thirty-fifth transistor T35 and a thirty-sixth transistor T36.

The thirty-fifth transistor T35 is an N-type MOS transistor and the thirty-sixth transistor T36 is a P-type MOS transistor.

A gate of the thirty-fifth transistor T35, a gate of the thirty-sixth transistor T36 and the second NOR gate sub-circuit NOR2 are electrically connected together.

A drain of the thirty-fifth transistor T35 is electrically connected to the second level signal line VGL, and a source of the twenty-eighth transistor T28 is electrically connected to the first level signal line VGH.

A source of the thirty-fifth transistor T35, a drain of the thirty-sixth transistor T36 and the fifth node E are electrically connected together.

In the embodiments of the present disclosure, for example, referring to FIG. 4, the fifth transistor T6 is an N-type MOS transistor. In the embodiments of the present disclosure, the end row control module S includes the third inverter NOT3, the fourth transmission gate TG4, the sixth transistor T6, the second NOR gate sub-circuit NOR2 and the fourth inverter NOT4; the end row control module 5 includes P-type MOS transistors and N-type MOS transistors, a positive voltage and a negative voltage output by the end row control module 5 have no loss, and the charging rate is fast and the efficiency is the same when outputting the positive voltage and the negative voltage, and thus the driving force of the driving circuit can be enhanced, and the display stability of the display device can be further improved.

In some embodiments of the present disclosure, referring to FIG. 4, the shift register module 6 includes a fifth inverter NOT5, a first tri-state inverter Tri-Inv1, a second tri-state inverter Tri-Inv2, a fifth transmission gate TGS, a sixth inverter NOT6, a seventh transistor T7 and an eighth transistor T8.

An input terminal of the fifth inverter NOTS is electrically connected to the first clock signal line, and an output terminal of the fifth inverter NOT5 is electrically connected to a first control terminal of the first tri-state inverter Tri-Inv1 and a second control terminal of the second tri-state inverter Tri-Inv2 respectively.

A second control terminal of the first tri-state inverter Tri-Inv1 is electrically connected to the first clock signal line, an input terminal of the first tri-state inverter Tri-Inv1 is electrically connected to the fifth node E, and an output terminal of the first tri-state inverter Tri-Inv1 is electrically connected to a gate of the seventh transistor T7 and an input terminal of the sixth inverter NOT6 respectively.

A first control terminal of the second tri-state inverter Tri-Inv2 is electrically connected to the first clock signal line, an input terminal of the second tri-state inverter Tri-Inv2 is electrically connected to a sixth node F, and an output terminal of the second tri-state inverter Tri-Inv2 is electrically connected to the gate of the seventh transistor T7 and the input terminal of the sixth inverter NOT6 respectively.

An output terminal of the sixth inverter NOT6 is electrically connected to the sixth node F and the second signal output terminal Sout of the driving unit at the current stage respectively.

A first control terminal of the fifth transmission gate TG5 is electrically connected to the output terminal of the first tri-state inverter Tri-1 and the output terminal of the second tri-state inverter Tri-Inv2 respectively, a second control terminal of the fifth transmission gate TG5 is electrically connected to the output terminal of the sixth inverter NOT6, an input terminal of the fifth transmission gate TG5 is electrically connected to the second clock signal line, and an output terminal of the fifth transmission gate TG5 is electrically connected to the first signal output terminal OUTN of the driving unit at the current stage.

A source of the seventh transistor T7 is electrically connected to the second level signal line VGL, a drain of the seventh transistor T7 is electrically connected to the first signal output terminal OUTN of the driving unit at the current stage, a gate of the eighth transistor T8 is electrically connected to the reset signal line Reset, a source of the eighth transistor T8 is electrically connected to the sixth node F, and a drain of the eighth transistor T8 is electrically connected to the second level signal line VGL.

It should be noted that in this specification, an end marked with a circle on a tri-state inverter symbol in FIG. 4 is the first control terminal of the tri-state inverter.

The tri-state inverter Tri-Inv includes a first control terminal, a second control terminal, an input terminal and an output terminal.

When the first control terminal is a low level signal and the second control terminal is a high level signal, if the input terminal of the tri-state inverter Tri-Inv inputs a high level signal, the output terminal outputs a low level signal; and if the input terminal of the tri-state inverter Tri-Inv inputs a low level signal, the output terminal outputs a high level signal.

When at least one of conditions that the first control terminal is a high level signal or the second control terminal is a low level signal is satisfied, the tri-state inverter Tri-Inv is turned off.

In the embodiments of the present disclosure, the first tri-state inverter Tri-Inv1 includes a thirty-ninth transistor T39, a fortieth transistor T40, a forty-first transistor T41 and a forty-second transistor T42.

The thirty-ninth transistor T39 is a P-type MOS transistor, the fortieth transistor T40 is a P-type MOS transistor, the forty-first transistor T41 is an N-type MOS transistor and the forty-second transistor T42 is an N-type MOS transistor.

A gate of the thirty-ninth transistor T39 is electrically connected to the output terminal of the fifth inverter NOTS, a source of the thirty-ninth transistor T39 is electrically connected to the first level signal line VGH, and a drain of the thirty-ninth transistor T39 is electrically connected to a source of the fortieth transistor T40.

A gate of the fortieth transistor T40, a gate of the forty-first transistor T41 and the fifth node E are electrically connected together.

A drain of the fortieth transistor T40, a source of the forty-first transistor T41 and the input terminal of the sixth inverter NOT6 are electrically connected together.

A drain of the forty-first transistor T41 and a source of the forty-second transistor T42 are electrically connected.

A gate of the forty-second transistor T42 is electrically connected to the first clock signal line, and a drain of the forty-second transistor T42 is electrically connected to the second level signal line VGL.

In the embodiments of the present disclosure, the second tri-state inverter Tri-Inv2 includes a forty-third transistor T43, a forty-fourth transistor T44, a forty-fifth transistor T45 and a forty-sixth transistor T46.

The forty-third transistor T43 is an N-type MOS transistor, the forty-fourth transistor T44 is an N-type MOS transistor, the forty-fifth transistor T45 is a P-type MOS transistor and the forty-sixth transistor T46 is a P-type MOS transistor.

A gate of the forty-third transistor T43 is electrically connected to the output terminal of the fifth inverter NOT5, a drain of the forty-third transistor T43 is electrically connected to the second level signal line VGL, and a source of the forty-third transistor T43 is electrically connected to a drain of the forty-fourth transistor T44.

A gate of the forty-fourth transistor T44, a gate of the forty-fifth transistor T45 and the sixth node F are electrically connected together.

A source of the forty-fourth transistor T44, a drain of the forty-fifth transistor T45 and the input terminal of the sixth inverter NOT6 are electrically connected together.

A of the forty-sixth transistor T46 is electrically connected to the first clock signal line. a source of the forty-sixth transistor T46 is electrically connected to the first level signal line VGH.

and a drain of the forty-sixth transistor T46 is electrically connected to a source of the forty-fifth transistor T45.

In the embodiments of the present disclosure, referring to FIG. 5 and FIG. 6, the fifth inverter NOTS includes a thirty-seventh transistor T37 and a thirty-eighth transistor T38.

The thirty-seventh transistor T37 is a P-type MOS transistor and the thirty-eighth transistor T38 is an N-type MOS transistor.

A gate of the thirty-seventh transistor T37, a gate of the thirty-eighth transistor T38 and the first clock signal line are electrically connected together.

A source of the thirty-seventh transistor T37 is electrically connected to the first level signal line VGH, and a drain of the thirty-eighth transistor T38 is electrically connected to the second level signal line VGL.

A drain of the thirty-seventh transistor T37, a source of the thirty-eighth transistor T38 and the first control terminal of the first tri-state inverter Tri-Inv1 are electrically connected together.

In the embodiments of the present disclosure, referring to FIG. 5 and FIG. 6, the sixth inverter NOT6 includes a forty-seventh transistor T47 and a forty-eighth transistor T48.

The forty-seventh transistor T47 is a P-type MOS transistor, and the forty-eighth transistor T48 is an N-type MOS transistor.

A gate of the forty-seventh transistor T47, a gate of the forty-eighth transistor T48 and the output terminal of the first tri-state inverter Tri-Inv1 are electrically connected together.

A source of the forty-seventh transistor T47 is electrically connected to the first level signal line VGH, and a drain of the forty-eighth transistor T48 is electrically connected to the second level signal line VGL.

A drain of the forty-seventh transistor T47, a source of the forty-eighth transistor T48 and the second signal output terminal Sout are electrically connected together.

In the embodiments of the present disclosure, referring to FIG. 5 and FIG. 6, the fifth transmission gate TG5 includes a forty-ninth transistor T49 and a fiftieth transistor T50.

The forty-ninth transistor T49 is an N-type MOS transistor and the fiftieth transistor T50 is a P-type MOS transistor.

A gate of the forty-ninth transistor T49 is electrically connected to the output terminal of the first tri-state inverter Tri-Inv1.

A source of the forty-ninth transistor T49 and a source of the fiftieth transistor T50 are electrically connected to the first signal output terminal OUTN of the driving unit at the current stage, and a drain of the forty-ninth transistor T49 and a drain of the fiftieth transistor T50 are electrically connected to the second clock signal line.

A gate of the fiftieth transistor T50 is electrically connected to the sixth node F.

In the embodiments of the present disclosure, referring to FIG. 4. for example, the seventh transistor T7 includes an N-type MOS transistor and the eighth transistor T8 includes an N-type MOS transistor.

In the embodiments of the present disclosure, the shift register module 6 includes the fifth inverter NOT5, the first tri-state inverter Tri-Inv1, the second tri-state inverter Tri-Inv2, the fifth transmission gate TG5, the sixth inverter NOT6, the seventh transistor T7 and the eighth transistor T8; the shift register module 6 includes P-type MOS transistors and N-type MOS transistors, a positive voltage and a negative voltage output by the shift register module 6 have no loss, and the charging rate is fast and the efficiency is the same when outputting the positive voltage and the negative voltage, and thus the driving force of the driving circuit can be enhanced, and the display stability of the display device can be further improved.

In some embodiments of the present disclosure, the latch module 2 includes a first transistor T1, a second transistor T2, a third transistor T3 and a fourth transistor T4; the start row trigger module 3 includes a fifth transistor 15; the end row control module 5 includes a sixth transistor T6, and the shift register module 6 includes a seventh transistor T7 and an eighth transistor T8.

The first transistor T1, the fourth transistor T4, the fifth transistor T5, the sixth transistor T6, the seventh transistor T7 and the eighth transistor T8 have the same polarity, the second transistor T2 and the third transistor T3 have the same polarity; and a polarity of the first transistor T1 is opposite to a polarity of the second transistor.

Next, taking the first transistor T1, the fourth transistor T4, the fifth transistor T5, the sixth transistor T6, the seventh transistor T7 and the eighth transistor T5 as all N-type transistors, and the second transistor T2 and the third transistor T3 as both P-type transistors, and selecting the third row as the switching start row and the sixth row as the switching end row in the forward scan mode as an example, the working principle of the driving circuit will be explained.

Referring to FIG. 9, in a resolution trigger display frame stage, a signal output by the first signal output terminal OUT3 of the driving unit connected to the third row of sub-pixels is consistent with the start row specified signal CGI.

In a resolution switching display frame stage, a signal output by the first signal output terminal OUT3 of the driving unit connected to the third row of sub-pixels is consistent with the start row specified signal CGI.

A falling edge of the trigger signal CGS is aligned with a rising edge of the start row specified signal CGI in the resolution switching display frame stage.

In the resolution switching display frame stage, the signal output by the first signal output terminal OUTN of the driving unit connected to the sixth row of sub-pixels is consistent with the end row specified signal CGE.

In FIG. 10, the fifth row is selected as the switching start row and the tenth row is selected as the switching end row. The timing regularity of each control signal and the working principle of each row are similar to the process of selecting the third row as the switching start row and the sixth row as the switching end row in FIG. 9. For details, refer to the description of FIG. 9 as an example, which will not be repeated here.

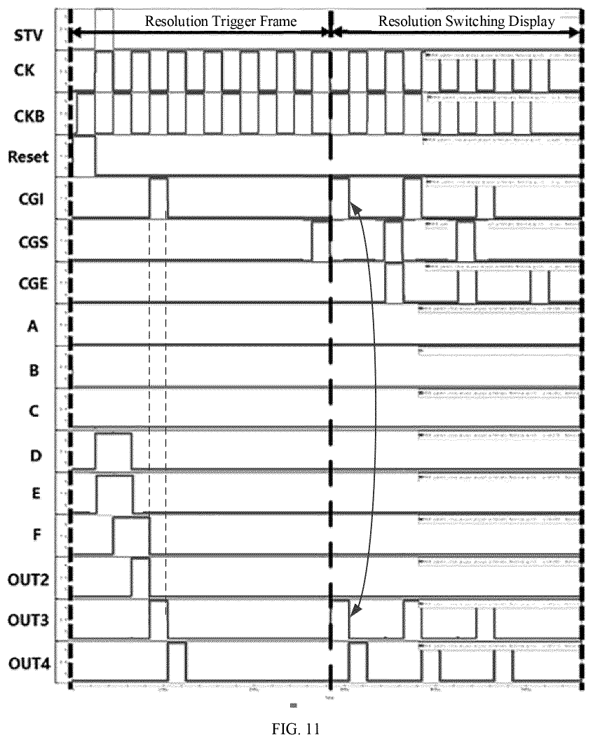

For the driving unit at a second stage (the driving unit connected to a previous row of the switching start row), referring to FIG. 11,
the first output signal OUT2 and a switching start row specified signal CGI will not be high level signals at the same time; the first NAND sub-circuit NAND1 outputs a high level signal, and after passing through the first inverter NOT1, the signal at the position of the first node A is a low level signal; the reset signal Reset is a low level signal, the first transistor T1 is turned off, the first NOR gate sub-circuit NOR1 has no high level signal input, the first NOR gate sub-circuit NOR1 outputs a high level signal, the fourth transistor T4 is turned on, the third transistor T3 is turned off, and the second node B inputs a low level signal VGL; the first transmission gate TG1 is turned off, the fifth transistor T5 is turned on, and the second level signal VGL is input to the third node C.

In the resolution trigger display frame stage, a switching end row specified signal COE is a low level signal, the fourth transmission gate TG4 is turned on, and the fifth transistor T5 is turned off. The first control signal CNB is a low level signal, the second control signal CN is a high level signal, and the second transmission gate TG2 is turned on. The forward scan signal STVF is a high level signal, and after passing through the second transmission gate TG2 and the fourth transmission gate TG4, the signal at the position of the fourth node D is a high level signal. The second NAND gate sub-circuit NOR2 inputs a high level signal, and the second NAND gate sub-circuit NOR2 outputs a low level signal, after passing through the fourth inverter NOT4, the signal at the position of the fifth node E is a high level signal. The first clock signal of a second row of sub-pixels is a CKB signal. When the first clock signal CKB is a high level signal, the first tri-state inverter Tri-Inv1 is turned on and the second tri-state inverter Tri-Inv2 is turned off, the first tri-state inverter Tri-Inv1 outputs a low level signal, and after passing through the fifth inverter NOT5, the signal at the position of the sixth node F is a high level signal, that is, the second output signal Sout is a high level signal, and the high level signal is input to the forward scan signal line STVF connected to the driving unit at a third stage. When the first clock signal CK is switched to a low level signal, the first tri-state inverter Tri-Inv1 is turned off, the second tri-state inverter Tri-Inv2 is turned on, the second tri-state inverter Tri-Inv2 outputs a high level signal, the fifth transmission gate TG5 is turned on, the seventh transistor T7 is turned off, the second clock signal CK is a high level signal, and the first signal output terminal OUT3 outputs a high level signal to scan the second row of sub-pixels.

In the resolution switching display frame stage, when the switching end row specified signal CGE is a low level signal, the fourth transmission gate TG4 is turned on, and the fifth transistor T5 is turned off. The forward scan signal STVF is a low level signal, and after passing through the second transmission gate TG2 and the fourth transmission gate TG4, the signal at the position of the fourth node D is a low level signal. When the switching end row specified signal CGE is a high level signal, the fourth transmission gate TG4 is turned off, the fifth transistor T5 is turned on, and the second level signal VGL is input at the position of the fourth node D. The signal at the position of the fourth node D remains a low level signal. The second NAND gate sub-circuit NOR2 inputs two low level signals, and the second NAND gate sub-circuit NOR2 outputs a high level signal, and after passing through the fourth inverter NOT4, the signal at the position of the fifth node E is a low level signal. When the first clock signal CKB is a high level signal, the first tri-state inverter Tri-Inv1 is turned on and the second tri-state inverter Tri-Inv2 is turned off, the first tri-state inverter Tri-Inv1 outputs a high level signal, and after passing through the fifth inverter NOT5, the signal at the position of the sixth node F is a low level signal, that is, the second output signal Sout is a low level signal, and the low level signal is input to the forward scan signal line STVF of the driving unit at the third stage. When the first clock signal CKB is switched to a low level signal, the first tri-state inverter Tri-Inv1 is turned off, the second tri-state inverter Tri-Inv2 is turned on, the second tri-state inverter Tri-Inv2 outputs a high level signal, the fifth transmission gate TGS is turned off, the seventh transistor T7 is turned on, the second level signal VGL output by the first signal output terminal OUT2 is a low level signal, and the data of the second row of sub-pixels is not updated.

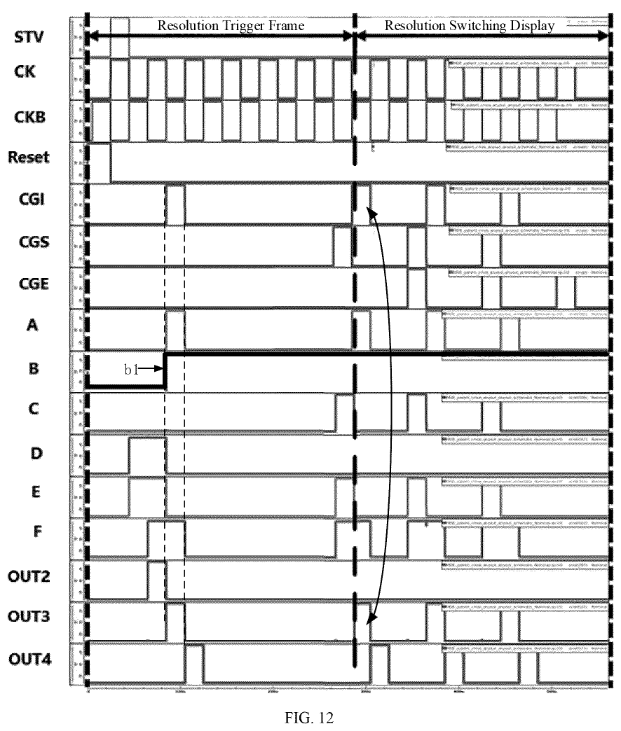

For the driving unit at the third stage (the driving unit connected to the switching start row), referring to FIG. 12,
the resolution trigger display frame stage, the first output signal OUT3 signal of the driving unit at the third stage and the start row specified signal CGI are both high level signals, the first NAND gate sub-circuit NAND1 outputs a low level signal, and after passing through the first inverter NOT1, the signal at the position of the first node A is a high level signal; the reset signal Reset is a low level signal, the first transistor T1 is turned off and the second transistor T2 is turned on; the input terminal of the first NOR gate sub-circuit NOR1 inputs a high level signal, the first NOR gate sub-circuit NOR1 outputs a low level signal, the third transistor T3 is turned on, the first level signal VGH output by the first level signal line reaches the second node B. the signal at the position of the second node B is a high level signal, and the second node B serves as an input terminal of the first NOR gate sub-circuit NOR2, the signal at the position of the first node A subsequently returns to a low level signal, the first NOR gate sub-circuit NOR1 and the second node B input a high level signal, the first NOR gate sub-circuit NOR1 outputs a low level signal, and the second node B of the driving unit at the third stage latches a high level signal at a position b1; the first transmission gate TG2 is turned on, the fifth transistor T5 is turned off, and the trigger signal CGS is input at the third node C; when the trigger signal CGS is a low level signal, the signal at the position of the third node C is a low level signal; and when the trigger signal CGS is a high level signal, the signal at the position of the third node C is a high level signal.

In the resolution switching display frame stage, the switching end row specified signal CGE is a low level signal, the fourth transmission gate TG4 is turned on, and the fifth transistor T5 is turned off. The first control signal CNB is a low level signal, the second control signal CN is a high level signal, and the second transmission gate TG2 is turned on. The forward scan signal STVF is a low level signal. and after passing through the second transmission gate TG2 and the fourth transmission gate TG4, the signal at the position of the fourth node D is a low level signal. When the trigger signal CGS is a high level signal, the signal at the position of the third node C is a high level signal, the second NAND gate sub-circuit NOR2 inputs a high level signal, the second NAND gate sub-circuit NOR2 outputs a low level signal, and after passing through the fourth inverter NOT4, the signal at the position of the fifth node E is a high level signal. The first clock signal of the third row of sub-pixels is a CK signal. When the first clock signal CK is a high level signal, the first tri-state inverter Tri-Inv2 is turned on, the second tri-state inverter Tri-Inv2 is turned off, the first tri-state inverter Tri-Inv1 outputs a low level signal, and after passing through the fifth inverter NOT5, the signal at the position of the sixth node F is a high level signal, that is, the second output signal Sout is a high level signal, and the high level signal is input to the forward scan signal line STVF connected to the driving unit at a fourth stage. When the first clock signal CK is switched to a low level signal, the first tri-state inverter Tri-Inv1 is turned off, the second tri-state inverter Tri-Inv2 is turned on, the second tri-state inverter Tri-Inv2 outputs a high level signal, the fifth transmission gate TG5 is turned on, the seventh transistor T7 is turned off, the second clock signal CKB is a high level signal, and the first signal output terminal OUT3 outputs a high level signal to scan the third row of sub-pixels.

The second node B of the driving unit at the third stage is latched as a high level signal after the first output signal OUT3 and the start row specified signal CGI are both high level signals for the first time, and thus in the resolution switching display frame stage, the start row specified signal CGI includes the following two situations.

First, in the resolution switching display frame stage, the signal OUTN output by the first signal output terminal of the driving unit connected to the start row is switched to be consistent with the start row specified signal CGI.

Second, in the resolution switching display frame stage, the start row specified signal CGI is a low level signal with constant voltage.

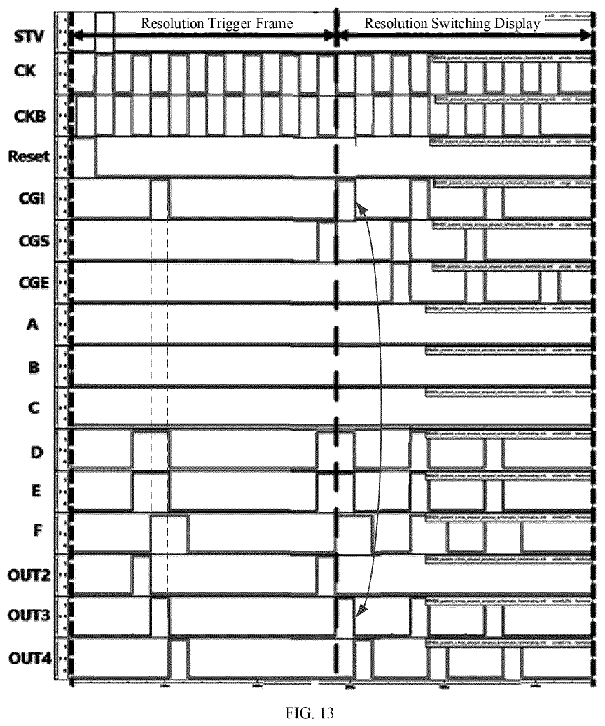

For the driving unit at the fourth stage (the driving unit connected to the switching start row), referring to FIG. 13,
the first output signal OUT4 and a switching start row specified signal CGI will not be high level signals at the same time; the first NAND sub-circuit NAND1 outputs a high level signal, and after passing through the first inverter NOT1, the signal at the position of the first node A is a low level signal; the reset signal Reset is a low level signal, the first transistor T1 is turned off, the first NOR gate sub-circuit NOR1 has no high level signal input, the first NOR gate sub-circuit NOR1 outputs a high level signal, the fourth transistor T4 is turned on, the third transistor T3 is turned off, and the second node B inputs a low level signal VGL; the first transmission gate TG1 is turned off, the fifth transistor T5 is turned on, and the second level signal VGL is input to the third node C.

In the resolution trigger display frame stage, a switching end row specified signal CGE is a low level signal, the fourth transmission gate TG4 is turned on, and the fifth transistor T5 is turned off. The first control signal CNB is a low level signal, the second control signal CN is a high level signal, and the second transmission gate TG2 is turned on. The forward scan signal STVF is a high level signal, and after passing through the second transmission gate TG2 and the fourth transmission gate TG4, the signal at the position of the fourth node D is a high level signal. The second NAND gate sub-circuit NOR2 inputs a high level signal, and the second NAND gate sub-circuit NOR2 outputs a low level signal, after passing through the fourth inverter NOT4, the signal at the position of the fifth node E is a high level signal. The first clock signal of a fourth row of sub-pixels is a CKB signal. When the first clock signal CKB is a high level signal, the first tri-state inverter Tri-Inv1 is turned on and the second tri-state inverter Tri-Inv2 is turned off, the first tri-state inverter Tri-Inv1 outputs a low level signal, and after passing through the fifth inverter NOT5, the signal at the position of the sixth node F is a high level signal, that is, the second output signal Sout is a high level signal, and the high level signal is input to the forward scan signal line STVF connected to the driving unit at a third stage. When the first clock signal CK is switched to a low level signal, the first tri-state inverter Tri-Inv1 is turned off, the second tri-state inverter Tri-Inv2 is turned on, the second tri-state inverter Tri-Inv2 outputs a high level signal, the fifth transmission gate TGS is turned on, the seventh transistor T7 is turned off, the second clock signal CK is a high level signal, and the first signal output terminal OUT3 outputs a high level signal to scan the fourth row of sub-pixels.

In the resolution switching display frame stage, when the switching end row specified signal CGE is a low level signal, the fourth transmission gate TG4 is turned on, and the fifth transistor T5 is turned off. When the second output signal Sout output by the driving unit at the third stage is a high level signal, the forward scan signal STVF of the driving unit at the fourth stage is a high level signal, and after passing through the second transmission gate TG2 and the fourth transmission gate TG4, the signal at the position of the fourth node D is a high level signal. The second NAND gate sub-circuit NOR2 inputs a high level signal, the second NAND gate sub-circuit NOR2 outputs a low level signal, and after passing through the fourth inverter NOT4, the signal at the position of the fifth node E is a high level signal. When the signal at the position of the fifth node E is a high level signal, the second output signal Sout is a high level signal, the high level signal is input to the forward scan signal line STVF of the driving unit at the fifth stage, and the first signal output terminal OUT4 outputs a high level signal to scan the fourth row of sub-pixels.

In this way, the driving circuit starts scanning line by line in the direction in which the number of rows of the sub-pixels increases from the third row of sub-pixels.

For the driving unit at a sixth stage (the driving unit connected to the switching start row), referring to FIG. 13,
the first output signal OUT4 and a switching start row specified signal CGI will not be high level signals at the same time; the first NAND sub-circuit NAND1 outputs a high level signal, and after passing through the first inverter NOT1, the signal at the position of the first node A is a low level signal; the reset signal Reset is a low level signal, the first transistor T1 is turned off, the first NOR gate sub-circuit NOR1 has no high level signal input, the first NOR gate sub-circuit NOR1 outputs a high level signal, the fourth transistor T4 is turned on, the third transistor T3 is turned off, and the second node B inputs a low level signal VGL; the first transmission gate TG1 is turned off, the fifth transistor T5 is turned on, and the second level signal VGL is input to the third node C.

In the resolution switching display frame stage, the driving circuit at the sixth stage will receive a high level forward scan signal STVF, the switching end row specified signal CGE is a low level signal, the fourth transmission gate TG4 is turned on, the sixth transistor T6 is turned off, the signal at the position of the fourth node D is a high level signal, and the signal at the position of the fifth node E is a high level signal. When the signal at the position of the fifth node E is a high level signal, the second output signal Sout is a high level signal, the high level signal is input to the forward scan signal line STVF of the driving unit at a seventh stage, and the first signal output terminal OUT6 outputs a high level signal to scan the sixth row of sub-pixels.

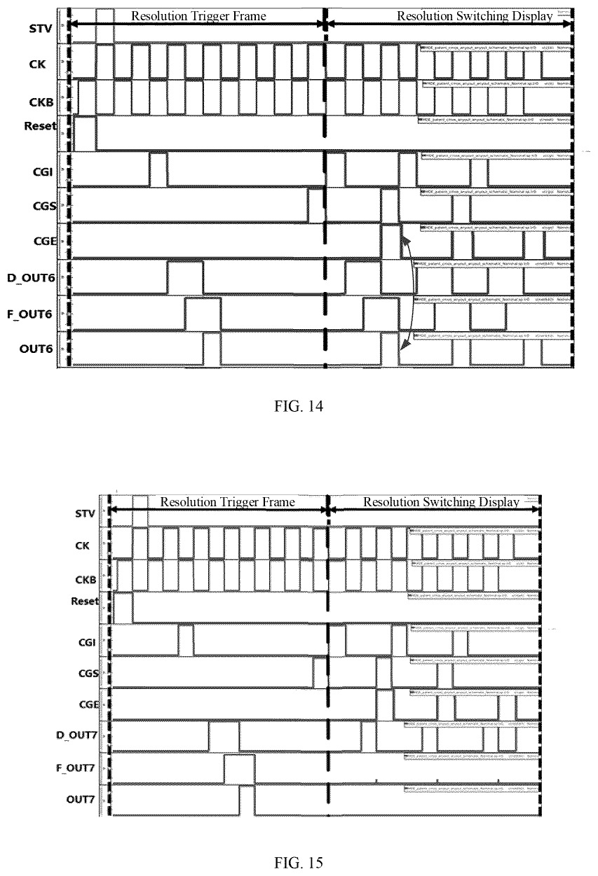

For the driving unit at the seventh stage (the driving unit connected to a next row of the switching start row), referring to FIG. 14,
in the resolution switching display frame stage, the driving unit at the seventh stage will receive the high level forward scan signal STVF output by the driving unit at the sixth stage, the switching end row specified signal CGE is a high level signal, the fourth transmission gate TG4 of the driving unit at the seventh stage is turned off, the sixth transistor T6 is turned on, the signal at the position of the fourth node D is a low level signal, and the signal at the position of the fifth node E is a low level signal; when the first clock signal CK is a high level signal, the first tri-state inverter Tri-Inv1 is turned on, and the signal at the position of the sixth node F is a low level signal, and the high level forward scan signal STVF is not output to the driving unit at an eighth stage; when the first clock signal CK is switched to a low level signal, the first tri-state inverter Tri-Inv1 is turned off, the second tri-state inverter Tri-Inv2 is turned on, the second tri-state inverter Tri-Inv2 outputs a high level signal, the fifth transmission gate TGS is turned off, the seventh transistor T7 is turned on, the second level signal VGL output by the first signal output terminal OUT7 is a low level signal, and the data of a seventh row of sub-pixels is not updated.

In this way, the driving circuit realizes scanning from the third row of sub-pixels to the sixth row of sub-pixels.

In some embodiments of the present disclosure, in the resolution trigger display frame stage, the signal OUTN output by the first signal output terminal OUTN of the driving unit connected to the switching start row is consistent with the start row specified signal CGI.

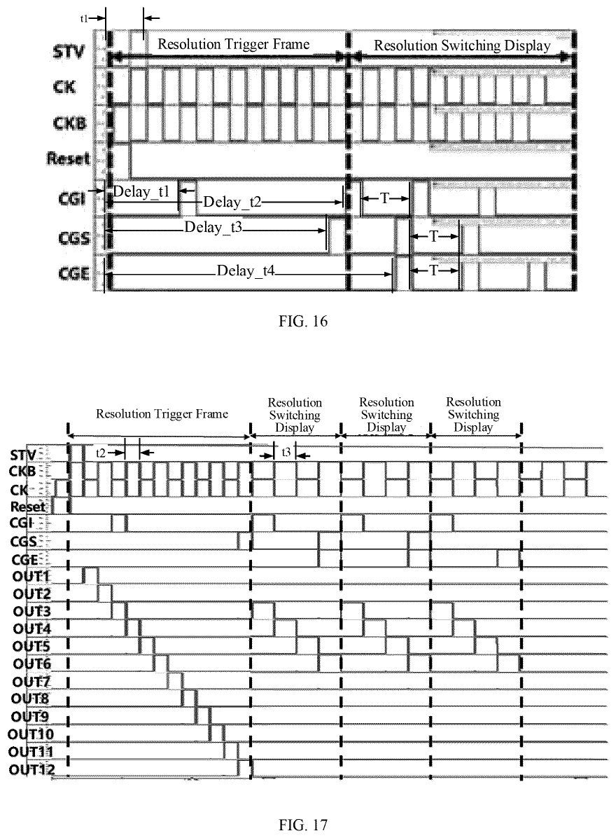

Taking a resolution of a display device as H*V as an example, where V is a number of rows of pixels, and H is a number of columns of the pixels. Referring to FIG. 16, t is a pulse width of a clock signal, and t1 is a time before a STV signal falls.

Taking the forward scan mode as an example, if the switching start row is the mth row, in the resolution trigger display frame stage, a timing of the start row specified signal CGI is:

$$Delay\_t1 = t I + ( m - 1 ) * t , \qquad ( 1 )$$

where Delay_t1 is a rising timing of the start row specified signal CGI.

For example, referring to FIG. 9, the switching start row is the third row of sub-pixels, in the resolution trigger display frame stage, the start row specified signal CGI rises at t1+2*t.

Since the second node B of the switching start row is latched as a high level signal after the first output signal OUTN and the start row specified signal CGI are both high level signals for the first time, in the resolution switching display frame stage, the start row specified signal CGI includes the following two situations.

First, in the resolution switching display frame stage, the signal OUTN output by the first signal output terminal of the driving unit connected to the start row is switched to be consistent with the start row specified signal CGI.

Second, in the resolution switching display frame stage, the start row specified signal CGI is a low level signal with constant voltage.

In the first situation, taking the forward scan mode as an example, if the switching start row is the mth row and the switching end row the nth row, in the resolution switching display frame stage, referring to FIG. 16, a timing of the start row specified signal CGI is:

$$Delay\_t2 = t 1 + V * t \{ m - [ Ceil ( m / h ) - 1 ] * h - 1 \} * t ; \qquad ( 2 )$$

$$T = ( n - m + 1 ) * t , \qquad ( 3 )$$

where T is a period of the start row specified signal CGI, Ceil is an upward rounding function, and h is a number of clock signals, for example, in the present disclosure, h is 2 (CK and CKB).

For example, referring to FIG. 9, the switching start row is the third row of sub-pixels, and the switching end row is the sixth row of sub-pixels. In the resolution switching display frame stage, the start row specified signal CGI rises at t1+12*t and rises once every 4t.

In some embodiments of the present disclosure, a falling edge of the trigger signal CGS is aligned with a rising edge of the start row specified signal CGI in the resolution switching display frame stage.

Referring to FIG. 16, in the resolution switching display frame stage, a timing of the trigger signal COS is:

$$Delay\_t3 = Delay\_t2 - t ; \qquad ( 4 )$$

$$T = ( n - m + 1 ) * t , \qquad ( 5 )$$

where T is a period of the trigger signal CGS.

For example, referring to FIG. 9, the switching start row is the third row of sub-pixels, and the switching end row is the sixth row of sub-pixels. The trigger signal CGS rises at t1+11*t and rises once every 4t.

In some embodiments of the present disclosure, in the resolution switching display frame stage, the signal output by the first signal output terminal OUTN of the driving unit connected to the switching end row is consistent with the end row specified signal CGE.

Referring to FIG. 16, in the resolution switching display frame stage, a timing of the end row specified signal CGE is:

$$Delay\_t4 = Delay\_t2 + ( n - m ) * t ; \qquad ( 6 )$$

$$T = ( n - m + 1 ) * t . \qquad ( 7 )$$

where T is a period of the end row specified signal CGE.

For example, referring to FIG. 9, the switching start row is the third row of sub-pixels, and the switching end row is the sixth row of sub-pixels. The end row specified signal CGE rises at t1+15*t and rises once every 4t.

In some embodiments of the present disclosure, referring to FIG. 17, a pulse width t2 of a clock signal in the resolution trigger display frame stage is less than a pulse width t3 of a clock signal in the resolution switching display frame stage.

In the resolution switching display frame stage, since the driving circuit only scans the sub-pixels between the switching start row and the switching end row, the pulse width of the clock signal can be increased without increasing a total time of one frame.

For example, as shown in FIG. 17, in the resolution trigger display frame stage, the driving circuit scans twelve rows of sub-pixels; and in the resolution switching display frame stage, the driving circuit scans four rows of sub-pixels, the pulse width t3 of the clock signal can be increased to be larger than the pulse width 12 of the clock signal in the resolution trigger display frame stage, the time of one frame does not increase, and the refresh rate will not decrease. In some embodiments of the present disclosure, the pulse width 12 of the clock signal in the resolution trigger display frame stage is less than the pulse width t3 of the clock signal in the resolution switching display frame stage, in the resolution trigger display frame stage, the charging time of each row of sub-pixels can be increased to avoid the problem of insufficient charging time of sub-pixels.

In some embodiments of the present disclosure, the driving unit connected to at least two adjacent rows of sub-pixels is electrically connected to a same clock signal line.

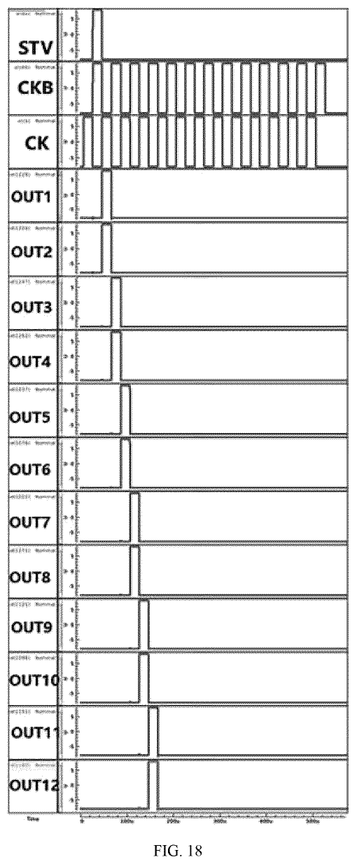

In some embodiments, referring to FIG. 18, the driving unit connected to two adjacent rows of sub-pixels is electrically connected to the same clock signal line, and two driving circuits simultaneously scan two adjacent rows of sub-pixels. In some embodiments, the driving unit connected to three adjacent rows of sub-pixels is electrically connected to the same clock signal line.

It should be noted that the driving unit connected to two adjacent rows of sub-pixels is electrically connected to the same clock signal line, which is different from the pixel driving unit in which one driving unit drives two rows of sub-pixels at the same time. In the former, each row of sub-pixels has a driving unit, which is electrically connected to the same clock signal; and in the latter, there is only one driving unit for two rows of sub-pixels.

In the embodiments of the present disclosure, the driving unit connected to at least two adjacent rows of sub-pixels is electrically connected to a same clock signal line. At least two rows of sub-pixels can be realized at the same time, and the resolution of the screen can be reduced, so that the pulse width can be increased, thereby increasing the charging time and avoiding the problem of insufficient charging in high frequency pixel rows.

Embodiments of the present disclosure provide a display device, including the driving circuit as described above.

The display device provided by the embodiments of the present disclosure can be a liquid crystal display (LCD) display device.

In addition, the display device can be a display device such as a display, and any product or component with a display function such as a television, a digital camera, a mobile phone and a tablet computer including the display device.

The embodiments of the present disclosure provide a display device, including a driving circuit. The driving circuit includes a plurality of driving units arranged in cascade, where each of the plurality of driving units is electrically connected to one or more rows of sub-pixels, and the driving unit includes: a start row control module 1 electrically connected to a first signal output terminal OUTN, a start row specified signal line CGI and a first node A of the driving unit at a current stage respectively, and configured to specify one of the rows of sub-pixels as a switching start row under a control of a start row specified signal CGI output by the start row specified signal line CGI; a latch module 2 electrically connected to the start row specified signal line CGI, a reset signal line Reset, a first level signal line (for example, a VGH line), a second level signal line (for example, a VGL line), the first node A and a second node B respectively, and configured to latch the start row specified signal CGI; and a start row trigger module 3 electrically connected to the second node B, a trigger signal line CGS, the second level signal line (for example, the VGL line) and a third node C respectively, and configured to trigger the switching start row to start scanning under a control of a trigger signal CGS output by the trigger signal line CGS. In this way, when full screen display is not needed or the electric quantity of the display device is relatively low, any row of sub-pixels can be specified as the switching start row, and scanning can be started from the specified switching start row, the data of some sub-pixels will not be updated, thereby reducing the power consumption of display and prolonging the standby time of the display device.

In some embodiments of the present disclosure, when a resolution of a picture displayed in the resolution switching display frame stage is less than or equal to half of a resolution of a picture displayed in the resolution trigger display frame stage, a refresh rate in the resolution switching display frame stage is greater than a refresh rate in the resolution trigger display frame stage.

When the resolution of the picture displayed in the resolution switching display frame stage is less than or equal to half of the resolution of the picture displayed in the resolution trigger display frame stage, without changing the pulse width of the clock signal, if a time for scanning a sub-pixel row is less than or equal to half of a time for scanning a full resolution sub-pixel row. the refresh rate in the resolution switching display frame stage can be increased.

For example, for a display device with a resolution of 1920*1080 and a refresh rate of 60 Hz in the display area AA, if a resolution of an area of the display screen becomes less than or equal to 960*1080 after switching the resolution, the refresh rate can be switched to 120 Hz. In some embodiments of the present disclosure, when the resolution of the picture displayed in the resolution switching display frame stage is less than or equal to half of the resolution of the picture displayed in the resolution trigger display frame stage, the refresh rate in the resolution switching display frame stage is greater than the refresh rate in the resolution trigger display frame stage, and thus the high refresh rate can be realized under the condition of low resolution, and the fluency of the picture can be improved.

The above is only the specific implementation of the present disclosure, but the protection scope of the present disclosure is not limited to this. Any skilled person familiar with this technical field can easily think of changes or replacements within the technical scope disclosed in the present disclosure, which should be covered within the protection scope of the present disclosure. Therefore, the protection scope of the present disclosure should be based on the protection scope of the claims.

1. A driving circuit, comprising: a plurality of driving units arranged in cascade, wherein each of the plurality of driving units is electrically connected to one or more rows of sub-pixels, and the driving unit comprises:
a start row control module electrically connected to a first signal output terminal, a start row specified signal line and a first node of the driving unit at a current stage respectively, and configured to specify one of the rows of sub-pixels as a switching start row under a control of a start row specified signal output by the start row specified signal line;
a latch module electrically connected to the start row specified signal line, a reset signal line, a first level signal line, a second level signal line, the first node and a second node respectively, and configured to latch the start row specified signal; and
a start row trigger module electrically connected to the second node, a trigger signal line, the second level signal line and a third node respectively, and configured to trigger the switching start row to start scanning under a control of a trigger signal output by the trigger signal line.

2. The driving circuit according to claim 1, wherein the driving unit further comprises:
a signal input module electrically connected to a first control signal line and a second control signal line respectively, and configured to input an enable signal to the switching start row under a common control of a signal output by the first control signal line and a signal output by the second control signal line and control the driving circuit to scan in a direction in which a number of rows of the sub-pixels decreases or in a direction in which the number of rows of the sub-pixels increases from the switching start row.

3. The driving circuit according to claim 2, wherein the driving unit further comprises:
an end row control module electrically connected to the third node, the signal input module, an end row specified signal line, the second level signal line and a fifth node respectively, and configured to specify one of the rows of sub-pixels as a switching end row under a control of the enable signal output by the signal input module, a signal at a position of the third node and an end row specified signal input by the end row specified signal line.

4. The driving circuit according to claim 3, wherein the driving unit further comprises:
a shift register module electrically connected to the fifth node, a first clock signal line, a second clock signal line, the reset signal line, the second level signal line, and the first signal output terminal and a second signal output terminal of the driving unit respectively, and configured to realize progressive scanning from the switching start row to the switching end row under a common control of a signal at a position of the fifth node, a first clock signal input by the first clock signal line and a second clock signal input by the second clock signal line.

5. The driving circuit according to claim 4, wherein the signal input module comprises a forward scan input submodule and a reverse scan input submodule, wherein the forward scan input submodule and the reverse scan input submodule are connected together and electrically connected to the end row control module;
the forward scan input submodule is electrically connected to a forward scan signal line, the first control signal line and the second control signal line respectively, and is configured to output a forward scan signal transmitted by the forward scan signal line under a common control of a first control signal input by the first control signal line and a second control signal input by the second control signal line; and
the reverse scan input submodule is electrically connected to a reverse scan signal line, the first control signal line and the second control signal line respectively, and is configured to output a reverse scan signal transmitted by the reverse scan signal line under the common control of the first control signal input by the first control signal line and the second control signal input by the second control signal line,
wherein the end row control module is configured to receive the forward scan signal or the reverse scan signal, wherein the forward scan signal is configured to control the driving circuit to scan in the direction in which the number of rows of the sub-pixels increases from the switching start row, and the reverse scan signal is configured to control the driving circuit to scan in the direction in which the number of rows of the sub-pixels decreases from the switching start row.

6. The driving circuit according to claim 1, wherein the start row control module comprises a first NAND gate sub-circuit and a first inverter,
wherein the first signal output terminal and the start row specified signal line of the driving unit at the current stage are electrically connected to two input terminals of the first NAND gate sub-circuit respectively, an input terminal of the first inverter is electrically connected to an output terminal of the first NAND gate sub-circuit, and an output terminal of the first inverter is electrically connected to the first node.

7. The driving circuit according to claim 1, wherein the latch module comprises a first transistor, a first NOR gate sub-circuit, a second transistor, a third transistor and a fourth transistor, wherein
a gate of the first transistor is electrically connected to the reset signal line, a source of the first transistor is electrically connected to the start row specified signal line, and a drain of the first transistor is electrically connected to an input terminal of the first NOR gate sub-circuit and the second node respectively;
two input terminals of the first NOR gate sub-circuit are electrically connected to the first node and the second node respectively, and an output terminal of the first NOR gate sub-circuit is electrically connected to a gate of the third transistor and a gate of the fourth transistor respectively;
a gate of the second transistor is electrically connected to the reset signal line, a source of the second transistor is electrically connected to the first level signal line, and a drain of the second transistor is electrically connected to a source of the third transistor; and
a drain of the third transistor, a source of the fourth transistor and the second node are electrically connected together, and a drain of the fourth transistor is electrically connected to the second level signal line.

8. The driving circuit according to claim 1, wherein the start row trigger module comprises a second inverter, a first transmission gate and a fifth transistor, wherein
an input terminal of the second inverter is electrically connected to the second node, and an output terminal of the second inverter is electrically connected to a gate of the fifth transistor and a first control terminal of the first transmission gate respectively;
a second control terminal of the first transmission gate is electrically connected to the second node, an input terminal of the first transmission gate is electrically connected to the trigger signal line, and an output terminal of the first transmission gate is electrically connected to the third node; and
a source of the fifth transistor is electrically connected to the second level signal line, and a drain of the fifth transistor is electrically connected to the third node.

9. The driving circuit according to claim 5, wherein the forward scan input submodule comprises a second transmission gate, and the reverse scan input submodule comprises a third transmission gate, wherein
a first control terminal of the second transmission gate is electrically connected to the first control signal line, a second control terminal of the second transmission gate is electrically connected to the second control signal line, an input terminal of the second transmission gate is electrically connected to the forward scan signal line, and an output terminal of the second transmission gate is connected to the end row control module;
a first control terminal of the third transmission gate is electrically connected to the second control signal line, a second control terminal of the third transmission gate is electrically connected to the first control signal line, an input terminal of the third transmission gate is electrically connected to the reverse scan signal line, and an output terminal of the third transmission gate is connected to the end row control module; and
the output terminal of the second transmission gate is connected to the output terminal of the third transmission gate.

10. The driving circuit according to claim 9, wherein the end row control module comprises a third inverter, a fourth transmission gate, a sixth transistor, a second NOR gate sub-circuit and a fourth inverter, wherein
an input terminal of the third inverter is electrically connected to the end row specified signal line and a gate of the sixth transistor, and an output terminal of the third inverter is electrically connected to a second control terminal of the fourth transmission gate;
a first control terminal of the fourth transmission gate is electrically connected to the input terminal of the third inverter, an input terminal of the fourth transmission gate is electrically connected to the signal input module, and an output terminal of the fourth transmission gate is electrically connected to a fourth node;
a source of the sixth transistor is electrically connected to the second level signal line, and a drain of the sixth transistor is electrically connected to the fourth node; and
two input terminals of the second NOR gate sub-circuit are electrically connected to the third node and the fourth node respectively, an output terminal of the second NOR gate sub-circuit is electrically connected to an input terminal of the fourth inverter, and an output terminal of the fourth inverter is electrically connected to the fifth node.

11. The driving circuit according to claim 10, wherein the shift register module comprises a fifth inverter, a first tri-state inverter, a second tri-state inverter, a fifth transmission gate, a sixth inverter, a seventh transistor and an eighth transistor, wherein
an input terminal of the fifth inverter is electrically connected to the first clock signal line, and an output terminal of the fifth inverter is electrically connected to a first control terminal of the first tri-state inverter and a second control terminal of the second tri-state inverter respectively;
a second control terminal of the first tri-state inverter is electrically connected to the first clock signal line, an input terminal of the first tri-state inverter is electrically connected to the fifth node, and an output terminal of the first tri-state inverter is electrically connected to a gate of the seventh transistor and an input terminal of the sixth inverter respectively;
a first control terminal of the second tri-state inverter is electrically connected to the first clock signal line, an input terminal of the second tri-state inverter is electrically connected to a sixth node, and an output terminal of the second tri-state inverter is electrically connected to the gate of the seventh transistor and the input terminal of the sixth inverter respectively;
an output terminal of the sixth inverter is electrically connected to the sixth node and the second signal output terminal of the driving unit at the current stage respectively;
a first control terminal of the fifth transmission gate is electrically connected to the output terminal of the first tri-state inverter and the output terminal of the second tri-state inverter respectively, a second control terminal of the fifth transmission gate is electrically connected to the output terminal of the sixth inverter, an input terminal of the fifth transmission gate is electrically connected to the second clock signal line, and an output terminal of the fifth transmission gate is electrically connected to the first signal output terminal of the driving unit at the current stage; and
a source of the seventh transistor is electrically connected to the second level signal line, a drain of the seventh transistor is electrically connected to the first signal output terminal of the driving unit at the current stage, a gate of the eighth transistor is electrically connected to the reset signal line, a source of the eighth transistor is electrically connected to the sixth node, and a drain of the eighth transistor is electrically connected to the second level signal line.

12. The driving circuit according to claim 11, wherein the latch module comprises a first transistor, a second transistor, a third transistor and a fourth transistor, and the start row trigger module comprises a fifth transistor,
wherein the first transistor, the fourth transistor, the fifth transistor, the sixth transistor, the seventh transistor and the eighth transistor have a same polarity, the second transistor and the third transistor have a same polarity, and a polarity of the first transistor is opposite to a polarity of the second transistor.

13. The driving circuit according to claim 12, wherein the first transistor, the fourth transistor, the fifth transistor, the sixth transistor, the seventh transistor and the eighth transistor are all N-type transistors, and the second transistor and the third transistor are all P-type transistors.

14. The driving circuit according to claim 1, wherein in a resolution trigger display frame stage, a signal output by the first signal output terminal of the driving unit connected to the switching start row is consistent with the start row specified signal.

15. The driving circuit according to claim 14, wherein in a resolution switching display frame stage, the signal output by the first signal output terminal of the driving unit connected to the switching start row is consistent with the start row specified signal; or
in a resolution switching display frame stage, the start row specified signal is a low level signal with a constant voltage; or a pulse width of a clock signal in the resolution trigger display frame stage is less than a pulse width of a clock signal in the resolution switching display frame stage.

16. (canceled)

17. The driving circuit according to claim 15, wherein a falling edge of the trigger signal is aligned with a rising edge of the start row specified signal in the resolution switching display frame stage.

18. The driving circuit according to claim 17, wherein in the resolution switching display frame stage, the signal output by the first signal output terminal of the driving unit connected to the switching end row is consistent with the end row specified signal.

19. (canceled)

20. The driving circuit according to claim 18, wherein the driving unit connected to at least two adjacent rows of sub-pixels is electrically connected to a same clock signal line.

21. A display device, comprising the driving circuit according to claim 1

22. The display device according to claim 21, wherein when a resolution of a picture displayed in the resolution switching display frame stage is less than or equal to half of a resolution of a picture displayed in the resolution trigger display frame stage, a refresh rate in the resolution switching display frame stage is greater than a refresh rate in the resolution trigger display frame stage.
